(19) United States
(12) Patent Application Publication
(10) Pub. No.: US 2011/0221066 A1
(43) Pub. Date: Sep. 15, 2011

(54) METHOD FOR MANUFACTURING A SEMICONDUCTOR DEVICE AND A SEMICONDUCTOR DEVICE

(76) Inventors: Kazuhiro WATANABE, Tokyo (JP); Toshitsune IIjima, Tokyo (JP)

(21) Appl. No.: 13/040,120

(22) Filed: Mar. 3, 2011

(30) Foreign Application Priority Data
Mar. 9, 2010 (JP) 2010-051428

(51) Int. Cl. H01L 21/782; H01L 23/48

(52) U.S. Cl. 257/773; 438/113; 257/E21.599; 257/E23.01

(57) ABSTRACT

A method for manufacturing a semiconductor device according to an aspect of the present invention includes the steps of: forming a metallic film; forming plural connecting conductors including engaging portions on the metallic film; forming a first resin; curing a second resin; forming a wiring pattern; forming a second external electrode; and cutting the second resin. The step of forming the first resin is the step of inserting and bringing a projected first external electrode provided in each of plural semiconductor chips in and into contact with each of the engaging portions of the plural connecting conductors, and forming a first resin between the plural semiconductor chips and the metallic film. The step of curing the second resin is the step of covering the plural semiconductor chips with the second resin to cure the second resin.

### CROSS REFERENCE TO RELATED APPLICATIONS

This application is based upon and claims the benefit of priority from the prior Japanese Patent Application No. 2010-051428 filed in Japan on Mar. 9, 2010; the entire contents of which are incorporated herein by reference.

### FIELD

Embodiments described herein relate generally to a method for manufacturing a semiconductor device in which a semiconductor chip is sealed by resin and a semiconductor device.

### BACKGROUND

Conventionally, there is well known a semiconductor device in which a semiconductor chip is sealed by resin. There is studied a method for easily manufacturing the semiconductor device at low cost by collectively forming the conventional plural semiconductor devices. The method will be described below.

After plural semiconductor chips are bonded to a retaining plate, the semiconductor chips on the retaining plate are collectively sealed by resin. Then the retaining plate is peeled off to form an insulating resin layer on the semiconductor chip. Then an opening is formed in the insulating resin layer such that an external electrode of the semiconductor chip is exposed. After the opening is formed, a wiring pattern is formed on the insulating resin layer, and a conductive portion is formed in the opening so as to be connected to the external electrode of the semiconductor chip. Then a solder resist layer and a solder ball are formed in this order on the insulating resin layer including the wiring pattern. Finally a resin sheet and the insulating resin layer are cut such that the plural semiconductor chips are individually divided.

In the present application, the above collective formation of the plural semiconductor devices means that, after the plural semiconductor chips are collectively sealed by the resin to form such as the wiring pattern, the plural semiconductor devices are divided by cutting the resin.

However, in the conventional method for the semiconductor device, the resin is shrunk by curing when the plural semiconductor chips are collectively sealed by the resin. Shrinkage amount of a resin is not always consistent with design thereof, which results in a problem in that the semiconductor chip is deviated from a design position after the resin is cured. When the position of the semiconductor chip is deviated, the opening is deviated from the position of the external electrode of the semiconductor chip in forming the opening of the insulating resin layer. Accordingly, unfortunately reliability of a connection between the conductive portion and the external electrode of the semiconductor chip is degraded. When the deviation of the opening becomes larger, sometimes the semiconductor chip is not connected to the conductive portion, which results in a problem in that a production yield is degraded.

### BRIEF DESCRIPTION OF THE DRAWINGS

FIG. 1 is a rear view illustrating a semiconductor device manufactured by a method for manufacturing the semiconductor device according to a first embodiment of the invention;

FIG. 2 is a sectional view taken on a chain line A-A′ of FIG. 1;

FIG. 3 is a rear view illustrating a semiconductor chip of FIGS. 1 and 2;

FIG. 4 is an enlarged top view illustrating a connecting plug of FIG. 2;

FIG. 5 is a view explaining the method for manufacturing the semiconductor device according to the first embodiment and a perspective view illustrating a support plate;

FIG. 6 is a sectional view taken on a chain line B-B′ of FIG. 5 in order to explain a connecting plug forming process in the method for manufacturing the semiconductor device according to the first embodiment;

FIG. 7 is a sectional view taken on the chain line B-B′ of FIG. 5 in order to explain the connecting plug forming process;

FIG. 8 is a sectional view taken on the chain line B-B′ of FIG. 5 in order to explain the connecting plug forming process;

FIG. 9 is a sectional view taken on the chain line B-B′ of FIG. 5 in order to explain a gold thin film forming process in the method for manufacturing the semiconductor device according to the first embodiment;

FIG. 10 is a sectional view taken on the chain line B-B′ of FIG. 5 in order to explain a semiconductor chip fixing process in the method for manufacturing the semiconductor device according to the first embodiment;

FIG. 11 is a sectional view taken on the chain line B-B′ of FIG. 5 in order to explain the semiconductor chip fixing process;

FIG. 12 is a sectional view taken on the chain line B-B′ of FIG. 5 in order to explain a process of sealing plural semiconductor chips in the method for manufacturing the semiconductor device according to the first embodiment;

FIG. 13 is a sectional view taken on the chain line B-B′ of FIG. 5 in order to explain a process of peeling off the support plate in the method for manufacturing the semiconductor device according to the first embodiment;

FIG. 14 is a sectional view taken on the chain line B-B′ of FIG. 5 in order to explain a wiring pattern forming process in the method for manufacturing the semiconductor device according to the first embodiment;

FIG. 15 is a sectional view taken on the chain line B-B′ of FIG. 5 in order to explain the wiring pattern forming process;

FIG. 16 is a sectional view taken on the chain line B-B′ of FIG. 5 in order to explain a resin cutting process in the method for manufacturing the semiconductor device according to the first embodiment;

FIG. 17 is a sectional view taken on the chain line A-A′ of FIG. 1 in order to explain a semiconductor device manufactured by a method for manufacturing the semiconductor device according to a second embodiment of the invention;

FIG. 18 is a sectional view taken on the chain line B-B′ of FIG. 5 in order to explain a semiconductor chip fixing process in the method for manufacturing the semiconductor device according to the second embodiment;

FIG. 19 is a sectional view taken on the chain line B-B′ of FIG. 5 in order to explain the semiconductor chip fixing process;

FIG. 20 is a sectional view taken on the chain line A-A′ of FIG. 1 in order to explain a semiconductor device manufactured by a method for manufacturing the semiconductor device according to a third embodiment of the invention;

FIG. 21 is a sectional view taken on the chain line B-B′ of FIG. 5 in order to explain a process of bonding a semiconductor chip to a base plate in the method for manufacturing the semiconductor device according to the third embodiment;

FIG. 22 is a sectional view taken on the chain line B-B′ of FIG. 5 in order to explain the process of bonding the semiconductor chip to the base plate;

FIG. 23 is a sectional view taken on the chain line B-B′ of FIG. 5 in order to explain a process of forming resin sealing the semiconductor chip in the method for manufacturing the semiconductor device according to the third embodiment;

FIG. 24 is a sectional view taken on the chain line B-B′ of FIG. 5 in order to explain a process of peeling off the support plate in the method for manufacturing the semiconductor device according to the third embodiment;

FIG. 25 is a sectional view taken on the chain line B-B′ of FIG. 5 in order to explain a semiconductor chip fixing process in the method for manufacturing the semiconductor device according to the third embodiment;

FIG. 26 is a sectional view taken on the chain line B-B′ of FIG. 5 in order to explain a resin cutting process in the method for manufacturing the semiconductor device according to the third embodiment;

FIG. 27 is a sectional view taken on the chain line A-A′ of FIG. 1 in order to explain a semiconductor device manufactured by a method for manufacturing the semiconductor device according to a fourth embodiment of the invention;

FIG. 28 is a sectional view taken on the chain line B-B′ of FIG. 5 in order to explain an upper layer of the semiconductor device in the method for manufacturing the semiconductor device according to the fourth embodiment;

FIG. 29 is a sectional view taken on the chain line B-B′ of FIG. 5 in order to explain a gold thin film forming process in the method for manufacturing the semiconductor device according to the fourth embodiment;

FIG. 30 is a sectional view taken on a chain line B-B′ of FIG. 5 in order to explain a process of forming a connecting plug and an interlayer connecting post in the method for manufacturing the semiconductor device according to the fourth embodiment;

FIG. 31 is a sectional view taken on a chain line B-B′ of FIG. 5 in order to explain the interlayer connecting post forming process in the method for manufacturing the semiconductor device according to the fourth embodiment;

FIG. 32 is a sectional view taken on the chain line B-B′ of FIG. 5 in order to explain the interlayer connecting post forming process;

FIG. 33 is a sectional view taken on the chain line B-B′ of FIG. 5 in order to explain a wiring pattern forming process in the method for manufacturing the semiconductor device according to the fourth embodiment;

FIG. 34 is a sectional view taken on the chain line B-B′ of FIG. 5 in order to explain a process of fixing a semiconductor chip of a lower layer in the method for manufacturing the semiconductor device according to the fourth embodiment;

FIG. 35 is a sectional view taken on the chain line B-B′ of FIG. 5 in order to explain a process of sealing the semiconductor chip of the lower layer by resin in the method for manufacturing the semiconductor device according to the fourth embodiment;

FIG. 36 is a sectional view taken on the chain line B-B′ of FIG. 5 in order to explain the wiring pattern forming process in the method for manufacturing the semiconductor device according to the fourth embodiment;

FIG. 37 is a sectional view taken on the chain line B-B′ of FIG. 5 in order to explain the wiring pattern forming process;

FIG. 38 is a sectional view taken on the chain line B-B′ of FIG. 5 in order to explain a resin cutting process in the method for manufacturing the semiconductor device according to the fourth embodiment;

FIG. 39 is a sectional view taken on the chain line A-A′ of FIG. 1 in order to explain a semiconductor device manufactured by a method for manufacturing the semiconductor device according to a fifth embodiment of the invention;

FIG. 40 is a sectional view taken on the chain line A-A′ of FIG. 1 in order to explain a semiconductor device manufactured by a method for manufacturing the semiconductor device according to a sixth embodiment of the invention;

FIG. 41 is an enlarged top view illustrating a connecting plug and a chip component connecting pad of FIG. 40;

FIG. 42 is a sectional view taken on a chain line B-B′ of FIG. 5 in order to explain a process of forming a connecting plug and a chip component connecting pad in the method for manufacturing the semiconductor device according to the sixth embodiment;

FIG. 43 is a sectional view taken on the chain line B-B′ of FIG. 5 in order to explain the process of forming the connecting plug and the chip component connecting pad;

FIG. 44 is a sectional view taken on the chain line B-B′ of FIG. 5 in order to explain the process of forming the connecting plug and the chip component connecting pad;

FIG. 45 is a sectional view taken on the chain line B-B′ of FIG. 5 in order to explain a gold thin film forming process in the method for manufacturing the semiconductor device according to the sixth embodiment;

FIG. 46 is a sectional view taken on the chain line B-B′ of FIG. 5 in order to explain a semiconductor chip fixing process in the method for manufacturing the semiconductor device according to the sixth embodiment;

FIG. 47 is a sectional view taken on the chain line B-B′ of FIG. 5 in order to explain the chip component fixing process in the method for manufacturing the semiconductor device according to the sixth embodiment;

FIG. 48 is a sectional view taken on the chain line B-B′ of FIG. 5 in order to explain a process of sealing the semiconductor chip and the chip component by resin in the method for manufacturing the semiconductor device according to the sixth embodiment;

FIG. 49 is a sectional view taken on the chain line B-B′ of FIG. 5 in order to explain a wiring pattern forming process in the method for manufacturing the semiconductor device according to the sixth embodiment;

FIG. 50 is a sectional view taken on the chain line B-B′ of FIG. 5 in order to explain the wiring pattern forming process;

FIG. 51 is a sectional view taken on the chain line B-B′ of FIG. 5 in order to explain the wiring pattern forming process;

FIG. 52 is a sectional view taken on the chain line B-B′ of FIG. 5 in order to explain a resin cutting process in the method for manufacturing the semiconductor device according to the sixth embodiment;

FIG. 53 is a sectional view taken on the chain line A-A′ of FIG. 1 in order to explain a semiconductor device manufactured by a method for manufacturing the semiconductor device according to a seventh embodiment of the invention;

FIG. 54 is a sectional view taken on the chain line A-A′ of FIG. 1 in order to explain a semiconductor device manufactured by a method for manufacturing the semiconductor device according to an eighth embodiment of the invention;

FIG. 55 is an enlarged sectional view taken on a chain line A-A′ of FIG. 1 in order to explain a connecting plug according to a first modification;

FIG. 56 is a top view illustrating the connecting plug of FIG. 55;

FIG. 57 is an enlarged sectional view taken on a chain line A-A′ of FIG. 1 in order to explain a connecting plug according to a second modification; and

FIG. 58 is a top view illustrating the connecting plug of FIG. 57.

### DETAILED DESCRIPTION

A method for manufacturing a semiconductor device according to an exemplary embodiment of the invention includes a process of forming a metallic film, a process of forming plural connecting conductors, a process of forming a first resin, a process of curing a second resin, a process of forming a wiring pattern, a process of forming a second external electrode, and a process of cutting the second resin. The process of forming the metallic film is one in which the metallic film is formed on a support plate. The process of the plural connecting conductors is one in which the plural connecting conductors including engaging portions are formed on the metallic film. The process of forming the first resin is one in which the first resin is formed between plural semiconductor chips and the metallic film while a projected first electrode provided in each of the plural semiconductor chips is inserted in and brought into contact with the engaging portion of the plural connecting conductors. The process of curing the second resin is one in which the plural semiconductor chips are covered with the second resin and cure the second resin. The process of forming the wiring pattern is one in which the wiring pattern connected electrically to the connecting conductor is formed by processing the metallic film. The process of forming the second external electrode is one in which the second external electrode is formed so as to be electrically connected to part of the wiring pattern. The process of cutting the second resin is one in which the second resin located around and above the plural semiconductor chips is cut.

The method for manufacturing the semiconductor device and the semiconductor device according to the embodiment will be described below with reference to the drawings.

### First Embodiment

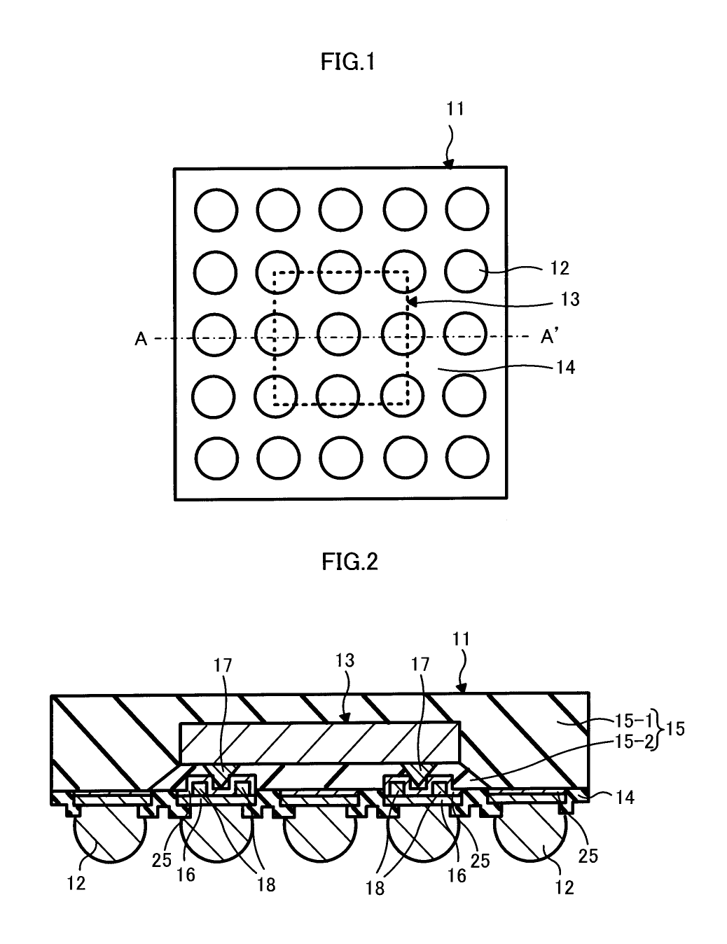

FIG. 1 is a rear view illustrating a semiconductor device 11 manufactured by a method for manufacturing the semiconductor device 11 according to a first embodiment of the invention. As illustrated in FIG. 1, plural solder balls 12 are formed into a lattice shape in a rear surface of the semiconductor device 11. The plural solder balls 12 are electrically connected to a semiconductor chip 13 sealed in the semiconductor device 11. The solder balls 12 constitute external electrodes of the semiconductor device 11. The semiconductor chip 13 in the semiconductor device 11 is electrically connected to wiring on a mounting board (not illustrated) through the solder balls 12. In the rear surface of the semiconductor device 11, for example, a region except the solder balls 12 are coated with a wiring protective film including a solder resist film 14.

FIG. 2 is a sectional view taken on a chain line A-A′ of FIG. 1. The semiconductor device 11 will be described in detail below with reference to FIG. 2. As illustrated in FIG. 2, in the semiconductor device 11, the semiconductor chip 13 is sealed by a resin 15 with which the surroundings of the semiconductor chip 13 are covered.

A wiring pattern 16 is formed on the rear surface of the resin 15 with which the semiconductor chip 13 is covered. The wiring pattern 16 is covered with the solder resist film 14. The solder resist film 14 with which the wiring pattern 16 is covered includes respective openings in regions where the solder balls 12 are formed. The solder balls 12 are formed in the openings to electrically connect the wiring pattern 16 and the solder balls 12. The wiring pattern 16 is partially extended to the outside of an outer peripheral portion of the semiconductor chip 13.

Plural projected electrodes 17 whose leading end portions are formed into acute shapes are formed in the rear surface of the semiconductor chip 13 of the resin 15. The plural projected electrodes 17 constitute the external electrodes of the semiconductor chip 13. The semiconductor chip 13 is electrically connected to the wiring pattern 16 through the projected electrodes 17.

For example, the projected electrode 17 is a stud bump. The stud bump is formed as follows. A ball bonding portion and a bonding wire portion, which are made of a material such as gold or copper, are formed on an electrode pad (not illustrated) of the semiconductor chip 13. The ball bonding portion and the bonding wire portion are mainly formed by thermocompression bonding in conjunction with an ultrasonic wave. After the electrode pad (not illustrated) of the semiconductor chip 13 and the ball bonding portion are bonded, the bonding wire portion is cut near the ball bonding portion. Therefore, the stud bump is formed through the above-described processes.

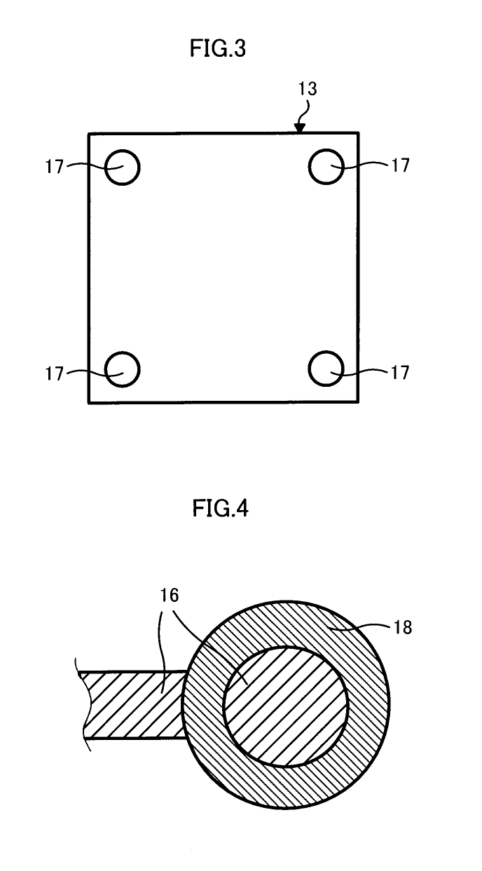

FIG. 3 is a rear view of the semiconductor chip 13. As illustrated in FIG. 3, for example, the projected electrode 17 is formed near four corner portions of the rear surface of the semiconductor chip 13.

Referring to FIG. 2, a connecting plug 18 that constitutes a connecting conductor is formed in a predetermined position of the wiring pattern 16 in order to electrically connect the wiring pattern 16 and the projected electrode 17. FIG. 4 is an enlarged top view of the connecting plug 18. As illustrated in FIG. 4, the connecting plug has a cylindrical shape. The cylindrical connecting plug 18 includes an engaging portion in which an opening is formed. The engaging portion has a diameter smaller than a maximum outer diameter of the projected electrode 17, and the engaging portion is formed so as to become lower than a level of the projected electrode 17.

Surfaces of the wiring pattern 16 and connecting plug 18 are coated with a gold thin film 25 in order to prevent oxidation of the surfaces. The thin film 25 is provided to suppress the oxidation of the surfaces of the wiring pattern 16 and connecting plug 18. Therefore, it is not always necessary to form the thin film 25.

Referring to FIG. 2, the projected electrode 17 is inserted in the cylindrical connecting plug 18 such that the connecting plug 18 is in partial contact with the projected electrode 17. Therefore, the projected electrode 17 of the semiconductor chip 13 engages the connecting plug 18, and the projected electrode 17 and the wiring pattern 16 are electrically connected through the connecting plug 18. On the wiring pattern 16, the connecting plugs 18 are formed as many as the projected electrodes 17 at points corresponding to positions of the projected electrodes 17 of the semiconductor chip 13.

The resin 15 with which the semiconductor chip 13 is covered includes a sealing resin 15-2 that is of the first resin such as an underfill resin and an insulating resin 15-1 that is of the second resin such as a mold resin. The sealing resin 15-2 is formed into a tapered shape such that a gap between the rear surface of the semiconductor chip 13 and the wiring pattern 16 is filled therewith. The insulating resin 15-1 is formed such that the upper surface and side face of the semiconductor chip 13 are coated therewith, and the insulating resin 15-1 is formed so as to be in contact with the sealing resin 15-2. The insulating resin 15-1 and the sealing resin 15-2 may be made of different materials as described above, or the insulating resin 15-1 and the sealing resin 15-2 may be made of the same material.

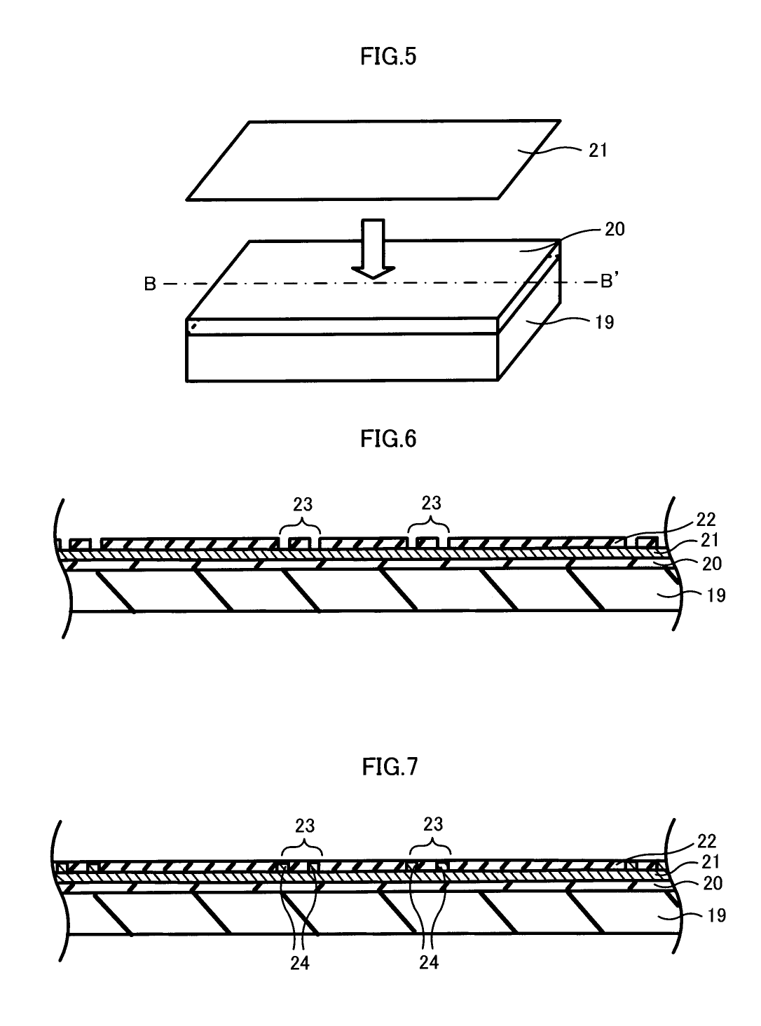

The method for manufacturing the semiconductor device 11 according to the first embodiment will be described below. In the method, after the plural semiconductor chips 13 are disposed such that the leading end portions of the projected electrodes are inserted in and brought into contact with the engaging portions of the connecting plugs 18, the plural semiconductor chips are collectively sealed by the resin 15, and the resin 15 is cut to obtain the divided semiconductor chip 13. The method will be described in detail below with reference to FIGS. 5 to 16. FIG. 5 is a perspective view of a support plate in order to explain the method for manufacturing the semiconductor device 11 according to the first embodiment, and FIGS. 6 to 16 are sectional views taken on the chain line B-B′ of FIG. 5 in order to explain the method for manufacturing the semiconductor device 11 according to the first embodiment.

As illustrated in FIG. 5, a metallic film 21 is bonded to a support plate 19 having a flat surface using a heat-resistant bonding agent 20. The metallic film 21 is one that constitutes the wiring pattern 16 through the subsequent process. For example, the support plate includes a glass plate. For example, the metallic film 21 includes a copper thin plate or a copper foil.

In addition to the heat-resistant bonding agent 20 that bonds the metallic film 21 to the support plate 19, a bonding agent whose adhesive force may be degraded by some sort of method such as a method for irradiating the bonding agent with an ultraviolet ray.

As illustrated in FIG. 6, a photosensitive resist 22 is uniformly formed on the metallic film 21. A cylindrical opening 23 is formed in the photosensitive resist 22 in order to form the connecting plug 18 later by exposing and developing the photosensitive resist 22. For example, the photosensitive resist 22 is formed on the metallic film 21 by a method using such as a spin coater.

As illustrated in FIG. 7, a metal 24 such as copper is formed in the cylindrical opening 23 by an electroplating method.

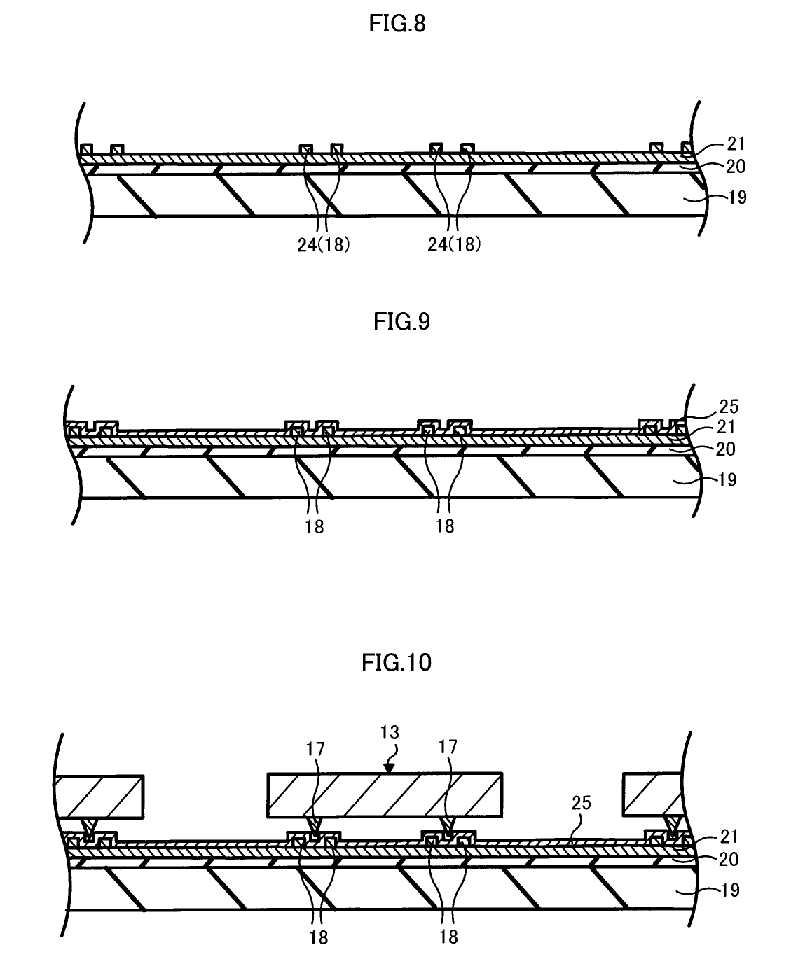

As illustrated in FIG. 8, the cylindrical metal 24 such as the copper remains on the metallic film 21 when the photosensitive resist 22 is removed by, for example, ashing. The cylindrical metal 24 remaining on the metallic film 21 constitutes the connecting plug 18.

As illustrated in FIG. 9, a gold thin film 25 is formed on the metallic film 21 including the connecting plug 18 by, for example, a CVD method. The thin film 25 is preferably to be formed, but not always necessary to be formed.

As illustrated in FIG. 10, the semiconductor chip 13 in which the projected electrodes 17 are formed is aligned, and the semiconductor chip 13 is disposed on the metallic film 21. The semiconductor chip 13 is disposed such that the projected electrode 17 is inserted in and brought into contact with the engaging portion of the connecting plug 18. When the semiconductor chip 13 is disposed in the above-described way, the projected electrode 17 engages the connecting plug 18, and the semiconductor chip 13 is fixed to a desired position on the support plate 19. The fixed semiconductor chip 13 is one that is determined to be non-defective by a previously-performed electric test of the semiconductor chip 13.

It is only necessary that the semiconductor chip 13 be positioned such that at least the leading end portion of the projected electrode 17 is located on the engaging portion of the connecting plug 18. Therefore, high-accuracy positioning is not required.

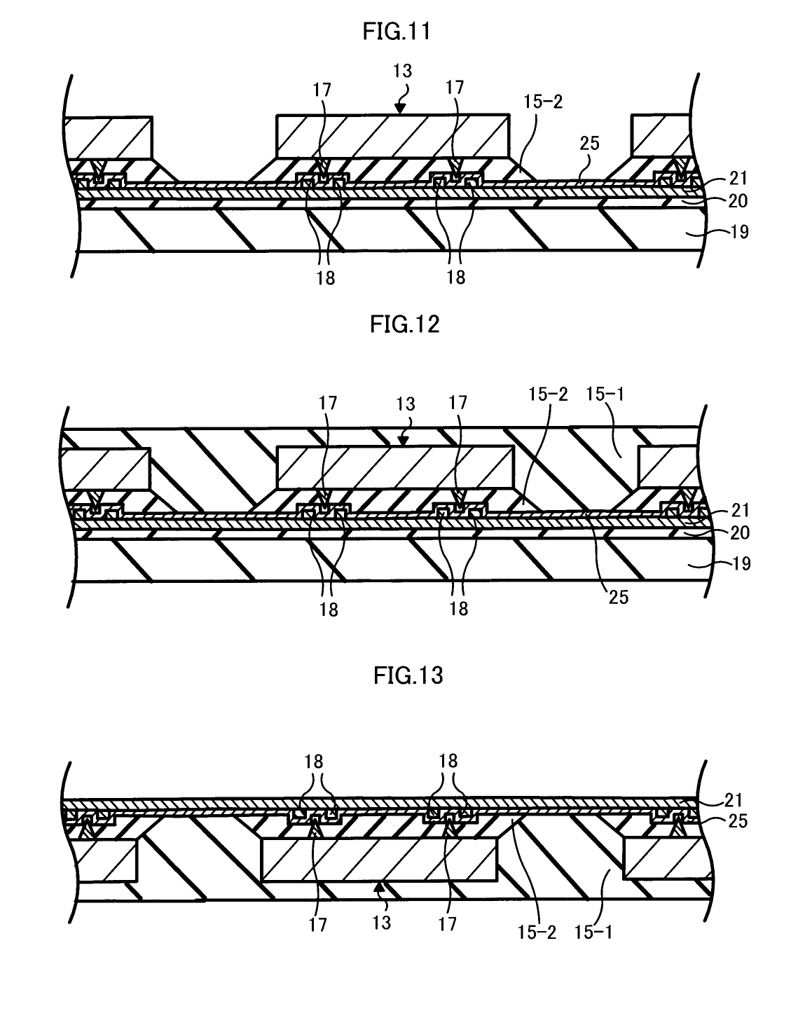

As illustrated in FIG. 11, the sealing resin 15-2 is formed between the metallic film 21 including the connecting plug 18 and the semiconductor chip 13. The semiconductor chip 13 is strongly fixed onto the metallic film 21 by the sealing resin 15-2. The sealing resin 15-2 is formed as follows.

After the semiconductor chip 13 is disposed and fixed as illustrated in FIG. 10, a sealing material that constitutes the sealing resin 15-2 is applied to the surroundings of the semiconductor chip 13. Therefore, the sealing material enters a gap between the metallic film 21 and the semiconductor chip 13 by capillarity. A baking treatment is performed after the sealing material enters the gap, whereby the tapered sealing resin 15-2 is formed upward from a bottom as illustrated in FIG. 11.

The process of forming the sealing resin 15-2 may be performed before the process of disposing and fixing the semiconductor chip 13 on the metallic film 21. That is, the semiconductor chip 13 is disposed on the sealing resin 15-2 after the sealing resin 15-2 is formed on the metallic film 21 including the connecting plug 18 prior to the process illustrated in FIG. 10. The semiconductor chip 13 may be fixed such that the projected electrode 17 penetrates through the sealing resin 15-2 to be inserted in and brought into contact with the engaging portion of the connecting plug 18 by pressing the semiconductor chip 13.

As illustrated in FIG. 12, the whole surface of the metallic film 21 including the semiconductor chip 13 is covered with the insulating resin 15-1, and the insulating resin 15-1 is cured. The plural semiconductor chips 13 are sealed by the insulating resin 15-1 and the sealing resin 15-2.

As illustrated in FIG. 13, after the heat-resistant bonding agent 20 is heated to a specific temperature or more to degrade the adhesive force, the support plate 19 (see FIG. 12) is peeled off from the metallic film 21. The whole is inverted after the support plate 19 is peeled off. When a bonding agent (for example, a bonding agent whose adhesive force is degraded by the irradiation of the ultraviolet ray) except the heat-resistant bonding agent 20 is applied, the support plate 19 may be peeled off from the metallic film 21 after the adhesive force is degraded by some sort of method (for example, the bonding agent is irradiated with the ultraviolet ray).

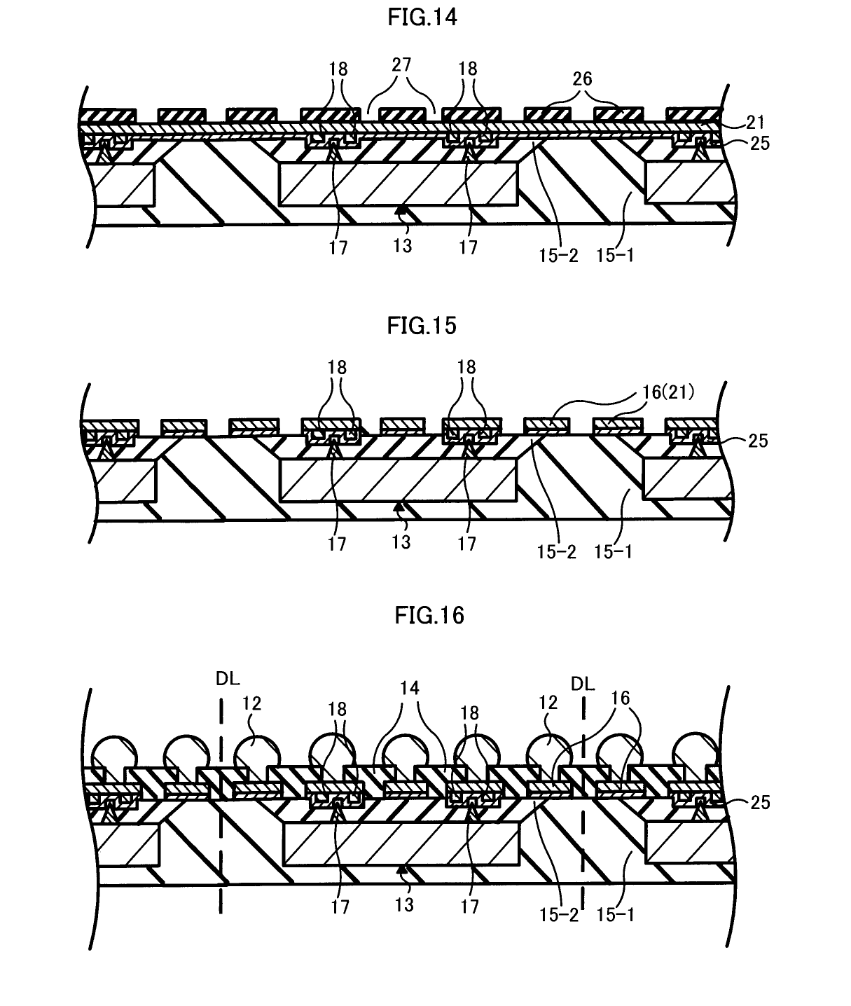

As illustrated in FIG. 14, a photosensitive resist 26 is applied on the rear surface of the metallic film 21. Then, the photosensitive resist 26 is exposed and developed using a mask that is opened into a desired pattern, thereby forming an opening in the photosensitive resist 26.

As illustrated in FIG. 15, the metallic film 21 and the gold thin film 25 are etched with the photosensitive resist 26 as the mask. The wiring pattern 16 is formed on the rear surface of the resin 15 including the insulating resin 15-1 and the sealing resin 15-2 by the etching.

Finally, as illustrated in FIG. 16, the solder resist film 14 is formed on the whole of the rear surface of the resin 15 including the wiring pattern 16. For example, the lattice-shaped opening is formed in the solder resist film 14 using a lithography technique. Then the solder ball 12 is formed in the lattice shaped opening. After the solder ball 12 is formed, the solder resist film 14 and the insulating resin 15-1 are cut along a dicing line DL. The semiconductor device 11 illustrated in FIGS. 1 and 2 are formed by cutting the solder resist film 14 and the insulating resin 15-1. The dicing line DL is defined such that each semiconductor chip 13 is formed without exposing the semiconductor chip 13 from the resin 15 when the solder resist film 14 and the insulating resin 15-1 are cut.

According to the method for manufacturing the semiconductor device according to the first embodiment, the plural semiconductor chips 13 are sealed by the insulating resin 15-1, after the semiconductor chips 13 are disposed and fixed such that the projected electrodes 17 of the semiconductor chips 13 are inserted in and brought into contact with the engaging portion of the connecting plugs 18. Accordingly, the position deviation of the semiconductor chip 13 is suppressed even if the insulating resin 15-1 is shrunk during the curing. Accordingly, a failure of the electric connection between the connecting plug 18 and the projected electrode 17 is suppressed, and the plural semiconductor devices 11 can collectively be formed without reducing the production yield.

The electric conduction is established between the projected electrode 17 and the connecting plug 18 by inserting the projected electrode 17 so as to be brought into contact with the engaging portion of the connecting plug 18. Alternatively, for example, there may be considered a method, in which the projected electrode 17 is formed by solder and the electric conduction between the projected electrode 17 and the connecting plug 18 is established by melting the projected electrode 17 in the engaging portion of the connecting plug 18. However, when the method is applied to the method for manufacturing the semiconductor device, it is necessary to form sizes and positions of the engaging portion of the connecting plug 18 and the projected electrode 17 with high accuracy.

For example, when the projected electrode 17 is formed smaller than a desired size, the accuracy can be lowered in the positions where the projected electrode 17 and the connecting plug 18 are formed. However, when the projected electrode 17 is melted in the engaging portion of the connecting plug 18, unfortunately a contact failure is generated due to a shortage of a volume of the projected electrode 17.

On the other hand, when the projected electrode is formed larger than the desired size, it is necessary to form the projected electrode 17 and the connecting plug 18 with high position accuracy. When the position of the projected electrode 17 is slightly deviated with respect to the connecting plug 18, the semiconductor chip 13 is sealed while the projected electrode 17 runs on the connecting plug 18. Accordingly, when the projected electrode 17 is heated and melted at this point, a space is generated in the portion in which the projected electrode 17 is formed, and the semiconductor chip 13 and the connecting plug 18 are not in contact with each other due to volume expansion of the resin, thereby generating the contact failure. Accordingly, even if the method of melting the projected electrode 17 in the engaging portion of the connecting plug 18 is adopted, it is difficult to suppress the contact failure between the projected electrode 17 and the engaging portion of the connecting plug 18.

As described above, according to the method for manufacturing the semiconductor device according to the first embodiment, the electric conduction between the projected electrode 17 and the connecting plug 18 is established by bringing the projected electrode 17 into contact with the connecting plug 18 while the projected electrode 17 is not melted. Accordingly, the failure of the electric connection associated with the melting of the projected electrode 17 is suppressed.

### Second Embodiment

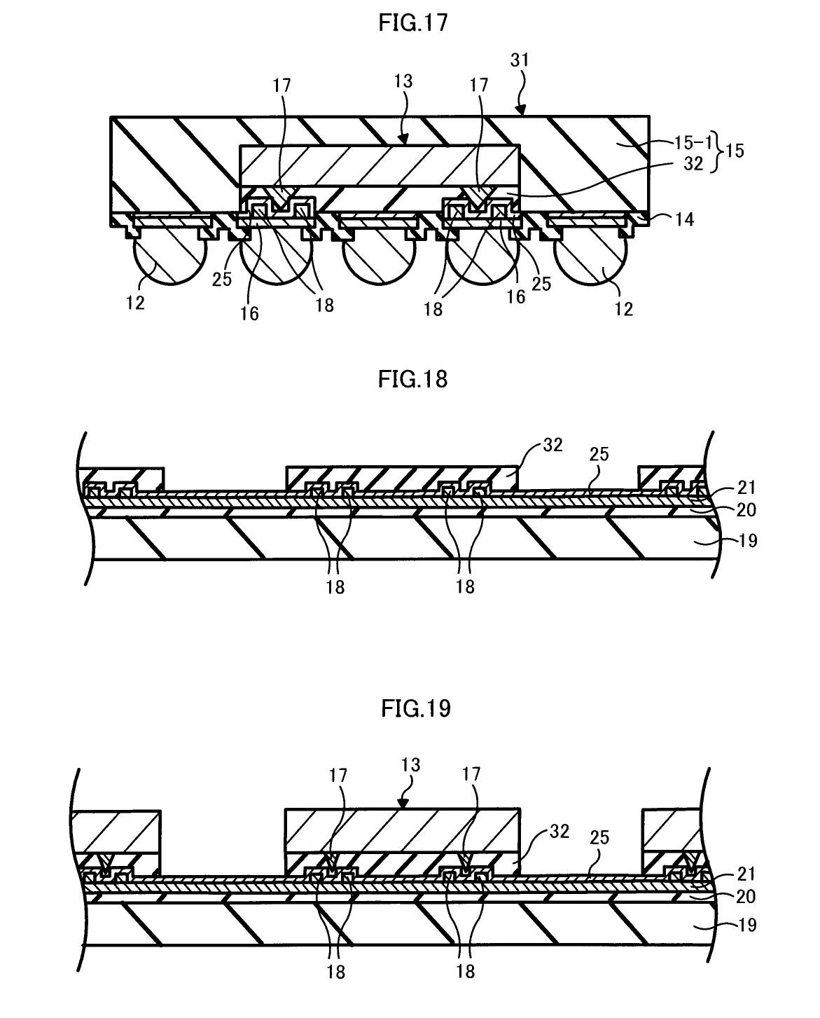

A semiconductor device manufactured by a method for manufacturing the semiconductor device according to a second embodiment of the invention will be described below. A rear view of the semiconductor device of the second embodiment is similar to that of FIG. 1. Accordingly, the semiconductor device manufactured by the method for manufacturing the semiconductor device according to the second embodiment will be described with reference to FIG. 17 that is of the sectional view taken on the chain line A-A′ of FIG. 1. In FIG. 17, the same part as the semiconductor device 11 of FIG. 2 is designated by the same numeral as the semiconductor device 11 of FIG. 1, and the description is omitted.

As illustrated in FIG. 17, a semiconductor device 31 differs from the semiconductor device 11 of FIG. 2 in that a bonding insulating sheet 32 is formed as the first resin between the semiconductor chip 13 and the wiring pattern 16. That is, the resin 15 with which the semiconductor chip 13 is covered includes the bonding insulating sheet 32 that is of the first resin and the insulating resin 15-1 that is of the second resin. The bonding insulating sheet 32 is a sheet-like insulating film including bonding surfaces in both surfaces thereof. The bonding insulating sheet 32 has a size that is substantially equal to a size of the rear surface of the semiconductor chip 13.

The method for manufacturing the semiconductor device 31 according to the second embodiment will be described below. The method differs from the method for manufacturing the semiconductor device 11 according to the first embodiment in the method of disposing and fixing the semiconductor chip 13. The method of disposing and fixing the semiconductor chip 13 in the method for manufacturing the semiconductor device 31 according to the second embodiment will be described below with reference to FIGS. 18 and 19. FIGS. 18 and 19 are sectional views taken on the chain line B-B′ of FIG. 5 in order to explain the method for manufacturing the semiconductor device according to the second embodiment.

In the method of disposing and fixing the semiconductor chip 13 in the method for manufacturing the semiconductor device 31 according to the second embodiment, as illustrated in FIGS. 8 and 9, the connecting plug 18 is formed and the gold thin film 25 is appropriately formed. Then, as illustrated in FIG. 18, the bonding insulating sheet 32 that is of the first resin having the size substantially equal to the size of the rear surface of the semiconductor chip 13 is bonded onto the metallic film 21 including the connecting plug 18.

As illustrated in FIG. 19, the projected electrode 17 and the connecting plug 18 are aligned with each other to dispose the semiconductor chip 13 on the bonding insulating sheet 32. Then, the semiconductor chip 13 is pressed from above such that the projected electrode 17 is inserted in and brought into contact with the connecting plug 18 by breaking through the bonding insulating sheet 32, thereby bonding and fixing the semiconductor chip 13 to the bonding insulating sheet 32. When the bonding insulating sheet 32 needs to be heated, it is necessary that the semiconductor chip 13 or the metallic film 21 be heated to bond and fix the semiconductor chip 13 to the bonding insulating sheet 32.

The subsequent processes are similar to those of FIGS. 12 to 16. The semiconductor device 31 illustrated in FIG. 17 is manufactured through the above-described processes.

Even in the method for manufacturing the semiconductor device 31 according to the second embodiment, the plural semiconductor chips 13 are sealed by the insulating resin 15-1, after the semiconductor chips 13 are disposed and fixed such that the projected electrodes 17 are inserted in and brought into contact with the engaging portions of the connecting plugs 18. Accordingly, the position deviation of the semiconductor chip 13 is suppressed even if the insulating resin 15-1 is shrunk during the curing. Accordingly, a failure of the electric connection between the connecting plug 18 and the projected electrode 17 is suppressed, and the plural semiconductor devices 31 can collectively be formed without reducing the production yield.

Even in the method for manufacturing the semiconductor device 31 according to the second embodiment, the electric conduction between the projected electrode 17 and the connecting plug 18 is established by bringing the projected electrode 17 into contact with the connecting plug 18 while the projected electrode 17 is not melted. Accordingly, the failure of the electric connection associated with the melting of the projected electrode 17 is suppressed.

### Third Embodiment

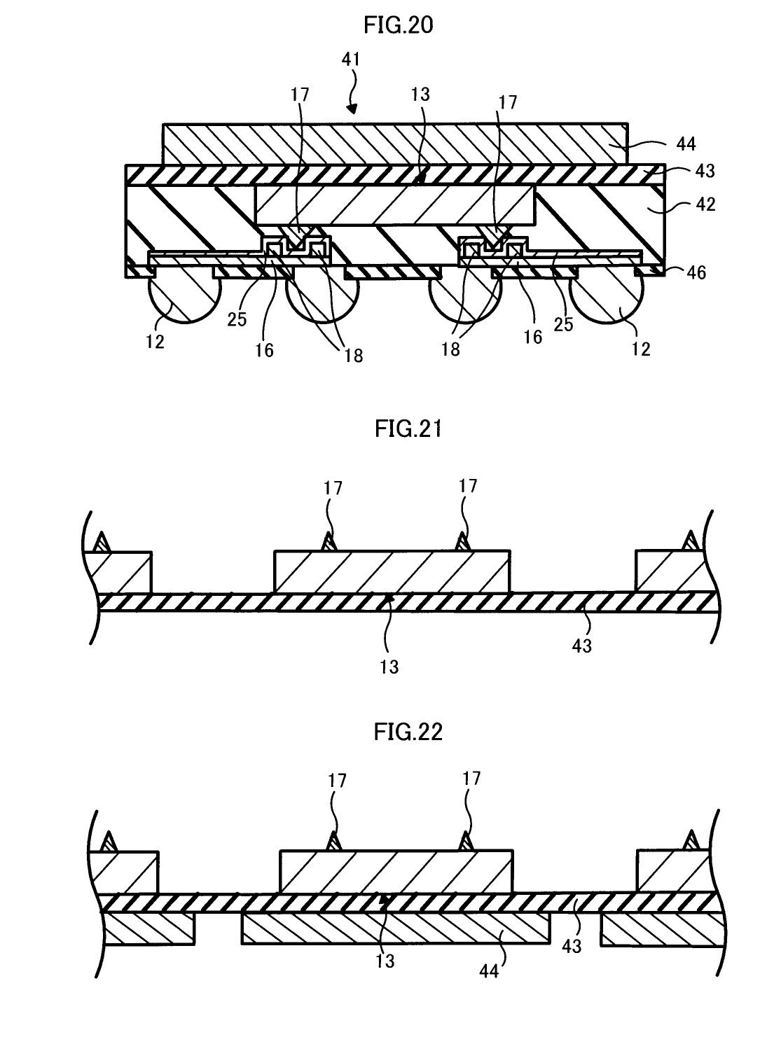

A semiconductor device manufactured by a method for manufacturing the semiconductor device according to a third embodiment of the invention will be described below. A rear view of the semiconductor device of the third embodiment is similar to that of FIG. 1. Accordingly, the semiconductor device manufactured by the method for manufacturing the semiconductor device according to the third embodiment will be described with reference to FIG. 20 that is of the sectional view taken on the chain line A-A′ of FIG. 1. In FIG. 20, the same part as the semiconductor device 11 of FIG. 2 is designated by the same numeral as the semiconductor device 11 of FIG. 1, and the description is omitted.

As illustrated in FIG. 20, in a semiconductor device 41, the surroundings except an upper surface of the semiconductor chip 13 is covered with a bonding insulating sheet 42, and a base plate 44 is bonded onto the bonding insulating sheet 42 including the upper surface of the semiconductor chip 13 while a double-side bonding sheet 43 is interposed therebetween.

The base plate 44 includes a plate having an excellent heat radiation property such as metallic plate made of copper, stainless steel, or the like or a ceramic plate. For example, the base plate is provided with the size larger than that of the semiconductor chip 13. The base plate 44 is provided in order to efficiently radiate the heat of the semiconductor chip 13 to the outside of the semiconductor device 41.

In the rear surface of the bonding insulating sheet 42 with which the semiconductor chip 13 is covered, the wiring pattern 16 and the connecting plug 18 that electrically connects the wiring pattern 16 and the projected electrode 17 of the semiconductor chip 13 are formed so as to be buried in the bonding insulating sheet 42. The wiring pattern 16 is partially extended to the outside of the outer peripheral portion of the semiconductor chip 13.

Preferably the surfaces of the wiring pattern 16 and connecting plug 18 are coated with the gold thin film 25 in order to prevent the oxidation of the surfaces. Although not illustrated, for example, preferably a nickel plating treatment is performed to the surface of the base plate 44 in order to prevent corrosion of the base plate 44.

A solder resist film 46 is formed on the rear surface of the bonding insulating sheet 42 including the wiring pattern 16 that is exposed from the rear surface of the bonding insulating sheet 42. Similarly to the first embodiment, the openings are formed in the regions where the solder balls 12 are formed in the solder resist film 46, and the solder balls 12 are formed in the openings.

The method for manufacturing p the semiconductor device 41 according to the third embodiment will be described below. In the method, the leading end portion of the projected electrode 17 of the semiconductor chip 13 is formed into the acute shape, the connecting plug 18 is formed into the cylindrical shape, and all the wiring patterns 16 including the connecting plug 18 are sealed by the bonding insulating sheet 42. Then, after the plural semiconductor chips 13 are disposed and fixed such that the projected electrodes 17 of the semiconductor chips 13 are inserted in and brought into contact with the engaging portion of the connecting plugs 18 by breaking through the bonding insulating sheet 42, the semiconductor chips 13 are divided by cutting the bonding insulating sheet 42. The method will be described in detail below with reference to FIGS. 21 to 26. FIGS. 21 to 26 are sectional views taken on the chain line B-B′ of FIG. 5 in order to explain the method for manufacturing the semiconductor device 41 according to the third embodiment.

As illustrated in FIG. 21, the upper surfaces of the semiconductor chips 13 in which the projected electrodes 17 are previously formed are bonded onto one of surfaces of the double-side bonding sheet 43 at equal intervals. As to the bonding of the semiconductor chip 13, for example, a usual alignment device recognizes an alignment mark (not illustrated) provided previously in a predetermined position of each semiconductor chip 13, and the semiconductor chip 13 is bonded such that the alignment marks are located at equal intervals.

As illustrated in FIG. 22, the base plate 44 is bonded to the other surface of the double-side bonding sheet 43 so as to face the semiconductor chip 13. The base plate 44 is aligned with the semiconductor chip 13 such that the usual alignment device recognizes the alignment mark of the semiconductor chip 13. The base plate 44 is accurately bonded in a predetermined position by this method.

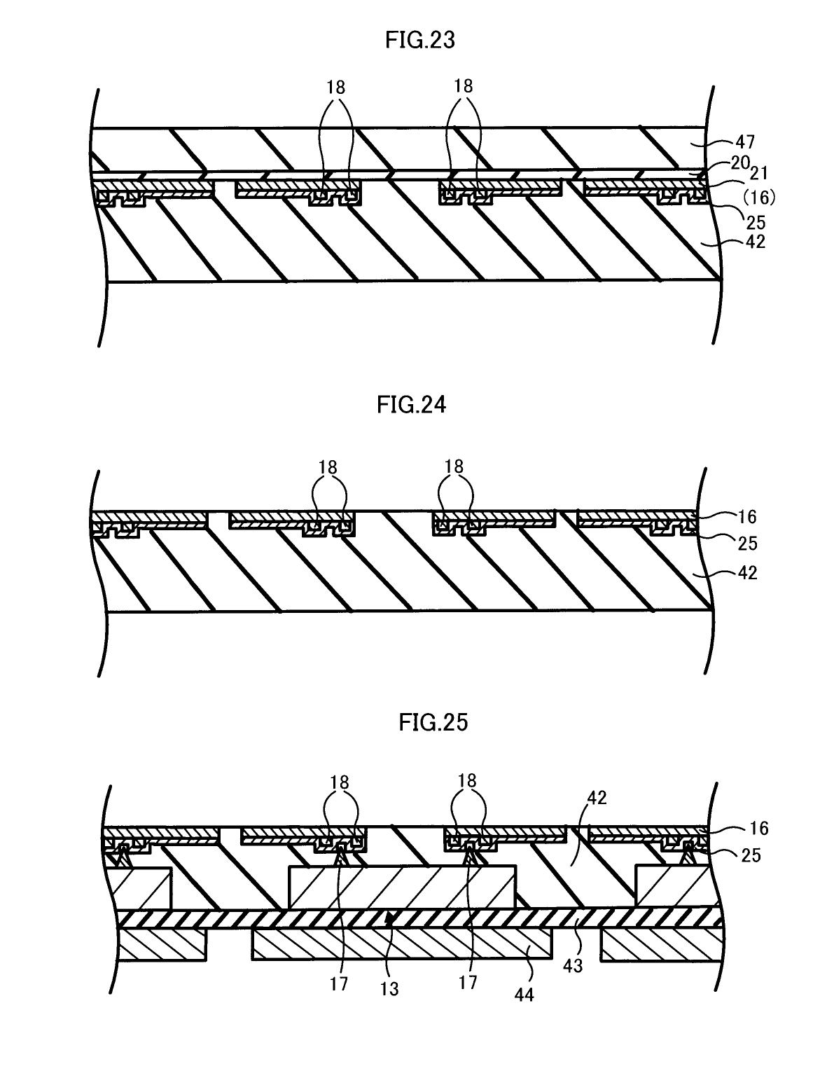

On the other hand, substantially similarly to the processes of FIGS. 5 to 8, for example, the copper metallic film 21 having the thin plate or foil shape is bonded to a support sheet 47 such as a polyimide tape corresponding to the support plate 19 by the heat-resistant bonding agent 20, and the connecting plug 18 is formed in a predetermined position on the metallic film 21. After the gold thin film 25 is appropriately formed on the connecting plug 18 and the metallic film 21, the wiring pattern 16 is formed by patterning the metallic film 21 and the gold thin film 25 as illustrated in FIG. 23. The bonding insulating sheet 42 made of resin is bonded to the surface of the heat-resistant bonding agent 20 including the wiring pattern 16 in which the connecting plug 18 is formed such that the connecting plug 18 and the wiring pattern 16 are buried. For example, the bonding insulating sheet 42 is bonded by laminating method.

Then, as illustrated in FIG. 24, the support sheet 47 (see FIG. 23) is peeled off from the bonding insulating sheet 42, and the whole is inverted. The method of peeling off the support sheet 47 is similar to that in the process of FIG. 13, and the method may appropriately be adopted according to the kind of the bonding agent that bonds the support sheet 47 and the bonding insulating sheet 42.

As illustrated in FIG. 25, the bonding insulating sheet 42 is bonded to the double-side bonding sheet 43 after the projected electrode 17 of the semiconductor chip 13 and the connecting plug 18 are aligned with each other. At this point, the semiconductor chip 13 is bonded by pressing the semiconductor chip 13 from above, such that the projected electrode 17 is inserted in and brought into contact with the connecting plug 18 by breaking through the bonding insulating sheet 42, and such that the semiconductor chip 13 is buried in the bonding insulating sheet 42. Then the bonding insulating sheet 42 is cured. When the bonding insulating sheet 42 needs to be heated in burying the plural semiconductor chips 13 in the bonding insulating sheet 42, it is necessary that the semiconductor chips 13 be heated to bond and fix the semiconductor chips 13 to the bonding insulating sheet 42.

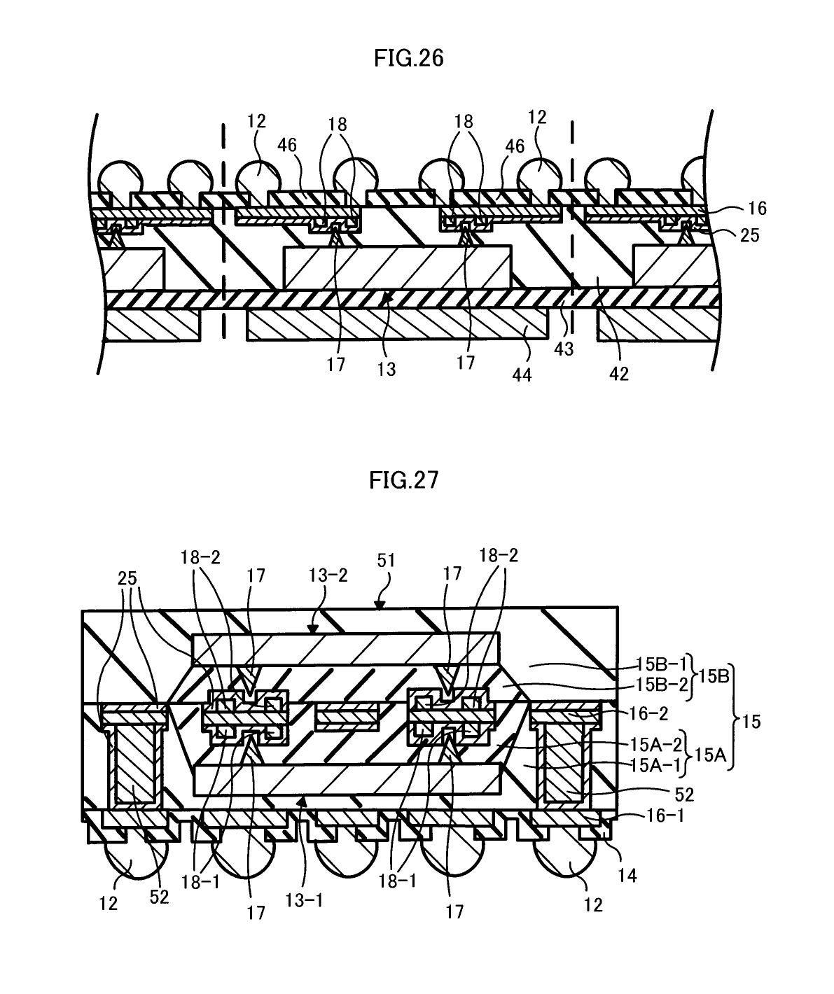

Finally, as illustrated in FIG. 26, the solder resist film 46 is formed on the whole surface of the bonding insulating sheet 42 including the wiring pattern 16 exposed to the surface. For example, the lattice-shaped opening is formed in the solder resist film 46 by the exposure and development processes. The solder ball 12 is formed in the opening formed in the solder resist film 46. After the solder ball 12 is formed, the solder resist film 46, the bonding insulating sheet 42, and the double-side bonding sheet 43 are cut along the dicing line DL, thereby manufacturing the semiconductor device 41 illustrated in FIG. 20.

Even in the method for manufacturing the semiconductor device 41 according to the third embodiment, the bonding insulating sheet 42 is cured, after the plural semiconductor chips 13 are disposed and fixed such that the projected electrodes 17 are inserted in and brought into contact with the engaging portions of the connecting plugs 18. Accordingly, the position deviation of the semiconductor chip 13 is suppressed even if the bonding insulating sheet 42 is shrunk during the curing. Accordingly, the failure of the electric connection between the connecting plug 18 and the projected electrode 17 is suppressed, and the plural semiconductor devices 41 can collectively be formed without reducing the production yield.

Even in the method for manufacturing the semiconductor device according to the third embodiment, the electric conduction between the projected electrode 17 and the connecting plug 18 is established by bringing the projected electrode 17 into contact with the connecting plug 18 while the projected electrode 17 is not melted. Accordingly, the failure of the electric connection associated with the melting of the projected electrode 17 is suppressed.

For example, the base plate 44, such as a metallic plate such as a copper plate having the good heat radiation property and a ceramic plate, which is made of a relatively hard material when a large amount of heat is generated in operating the semiconductor chip 13. The generated heat can efficiently be radiated by the use of the base plate 44. On the other hand, the base plate 44 is individually formed. Accordingly, the portion that is cut in the cutting process of the final process is a resin portion that is presumed to be the bonding insulating sheet 42, so that the cutting can easily be performed. Therefore, generation of a cutting burr is suppressed without adopting the special cutting method, and the high-quality, high-reliability semiconductor devices 41 can collectively be formed.

The method for manufacturing the semiconductor device 41 illustrated in FIG. 20 is not limited to the method according to the third embodiment. For example, the semiconductor device 41 can be manufactured by a method for manufacturing a semiconductor device according to a modification of the method for manufacturing the semiconductor device 41 according to the third embodiment.

(Modification of the Method for Manufacturing the Semiconductor Device according to the Third Embodiment)

In the modification of the method for manufacturing the semiconductor device according to the third embodiment, the wiring pattern 16 is not formed in a process of FIG. 23. The wiring pattern 16 is formed as follows. That is, in the state of the metallic film 21 in which the connecting plug 18 is formed, the bonding insulating sheet 42 is bonded to the double-side bonding sheet 43 to which the semiconductor chip 13 is bonded such that the semiconductor chip 13 is covered with the bonding insulating sheet 42 as illustrated in FIG. 25. The metallic film 21 and the gold thin film 25 are patterned after the bonding insulating sheet 42 is bonded to the double-side bonding sheet 43. The wiring pattern 16 is formed as described above.

After the wiring pattern 16 is formed, the solder resist film 46 and the solder ball 12 are formed in this order on the bonding insulating sheet 42 including the wiring pattern 16. Finally, the bonding insulating sheet 42 and the double-side bonding sheet 43 are cut along the dicing line DL. The semiconductor device corresponding to the semiconductor device 41 of FIG. 20 can be manufactured by cutting the bonding insulating sheet and the double-side bonding sheet 43. The semiconductor device manufactured by the method of the modification is similar to the semiconductor device 41 illustrated in FIG. 20 except that the wiring pattern 16 is not buried in the bonding insulating sheet 42.

Even in the modification of the method according to the third embodiment, the reduction of production yield caused by the contact failure between the projected electrode 17 and the connecting plug 18 can be suppressed for the same reason as the method for manufacturing the semiconductor device according to the third embodiment. The high-quality, high-reliability semiconductor devices can collectively be manufactured without adopting the special cutting method.

### Fourth Embodiment

A semiconductor device manufactured by a method for manufacturing the semiconductor device according to a fourth embodiment of the invention will be described below. A rear view of the semiconductor device of the fourth embodiment is similar to that illustrated in FIG. 1. Accordingly, the semiconductor device produced by the semiconductor device producing method of the fourth embodiment will be described with reference to FIG. 27 that is of the sectional view taken on the chain line A-A′ of FIG. 1. In FIG. 27, the same part as the semiconductor device 11 illustrated in FIG. 2 is designated by the same numeral as the semiconductor device 11 illustrated in FIG. 1, and the description is omitted.

As illustrated in FIG. 27, a semiconductor device 51 includes two layers of an upper layer and a lower layer. A first semiconductor chip 13-1 is disposed in the lower layer while a second semiconductor chip 13-2 is disposed in an upper layer, and the first semiconductor chip 13-1 and the second semiconductor chip 13-2 are covered with the resin 15. That is, a semiconductor device 51 is a multi-chip module on which the first semiconductor chip 13-1 and the second semiconductor chip 13-2 are densely mounted. The first semiconductor chip 13-1 and the second semiconductor chip 13-2 may be identical to or different from each other. The first semiconductor chip 13-1 and the second semiconductor chip 13-2 are the semiconductor chip including the projected electrodes 17 illustrated in FIG. 3.

The resin 15 includes a first resin layer 15A with which the first semiconductor chip 13-1 is covered and a second resin layer 15B with which the second semiconductor chip 13-2 is covered. The second resin layer 15B is stacked on the first resin layer 15A.

The first resin layer 15A includes a sealing resin 15A-2 that is of the first resin such as an underfill resin and an insulating resin 15A-1 that is of the second resin such as a mold resin. The sealing resin 15A-2 is formed into a tapered shape such that a gap between the rear surface of the first semiconductor chip 13-1 and a later described second wiring pattern 16-2 is filled therewith. The insulating resin 15A-1 is formed such that the surroundings except the lower surface of the first semiconductor chip 13-1 is in contact with the sealing resin 15A-2.

Similarly the second resin layer 15B includes an insulating resin 15B-1 such as the mold resin and a sealing resin 15B-2 such as the underfill resin. The sealing resin 15B-2 is formed into the tapered shape such that a gap between the rear surface of the second semiconductor chip 13-2 and the later described second wiring pattern 16-2 is filled therewith. The insulating resin 15B-1 is formed such that the surroundings except the lower surface of the second semiconductor chip 13-2 is in contact with the sealing resin 15B-2.

The insulating resins 15A-1 and 15B-1 and the sealing resins 15A-2 and 15B-2 may be made of different materials as described above, or the insulating resins 15A-1 and 15B-1 and the sealing resins 15A-2 and 15B-2 may be made of the same material.

A first wiring pattern 16-1 is formed on the rear surface of the first resin layer 15A. The first wiring pattern 16-1 is covered with the solder resist film 14. The solder resist film 14 includes openings in regions where the solder balls 12 are formed. The solder balls 12 are formed in the openings to electrically connect the first wiring pattern 16-1 and the solder balls 12. The second wiring pattern 16-2 is formed on the surface of the first resin layer 15A so as to be buried in the first resin layer 15A.

The first wiring pattern 16-1 and the second wiring pattern 16-2 are electrically connected by plural columnar interlayer connecting posts 52. The interlayer connecting post 52 is formed so as to penetrate the first resin layer 15A. Although not illustrated, the first wiring pattern 16-1 and the second wiring pattern 16-2 are partially extended to the outsides of outer peripheral portions of the first and second semiconductor chips 13-1 and 13-2.

A first connecting plug 18-1 is formed in a predetermined position on the rear surface of the second wiring pattern 16-2. A second connecting plug 18-2 is formed in a predetermined position on the surface of the second wiring pattern 16-2. The first and second connecting plugs 18-1 and 18-2 are formed into the cylindrical shape as illustrated in FIG. 4. Preferably the surfaces of the surroundings of the second wiring pattern 16-2, the first and second connecting plugs 18-1 and 18-2, and interlayer connecting post 52 are coated with the gold thin film 25 in order to prevent the oxidation of the surfaces.

The projected electrode 17 of the first semiconductor chip 13-1 is inserted in and brought into contact with the engaging portion of the first connecting plug 18-1. The projected electrode 17 is inserted in and brought into contact with the engaging portion of the first connecting plug 18-1, whereby the projected electrode 17 of the first semiconductor chip 13-1 and the second wiring pattern 16-2 are electrically connected to each other. Similarly the projected electrode 17 of the second semiconductor chip 13-2 is inserted in and brought into contact with the engaging portion of the second connecting plug 18-2. The projected electrode 17 is inserted in and brought into contact with the engaging portion of the second connecting plug 18-2, whereby the projected electrode 17 of the second semiconductor chip 13-2 and the second wiring pattern 16-2 are electrically connected to each other.

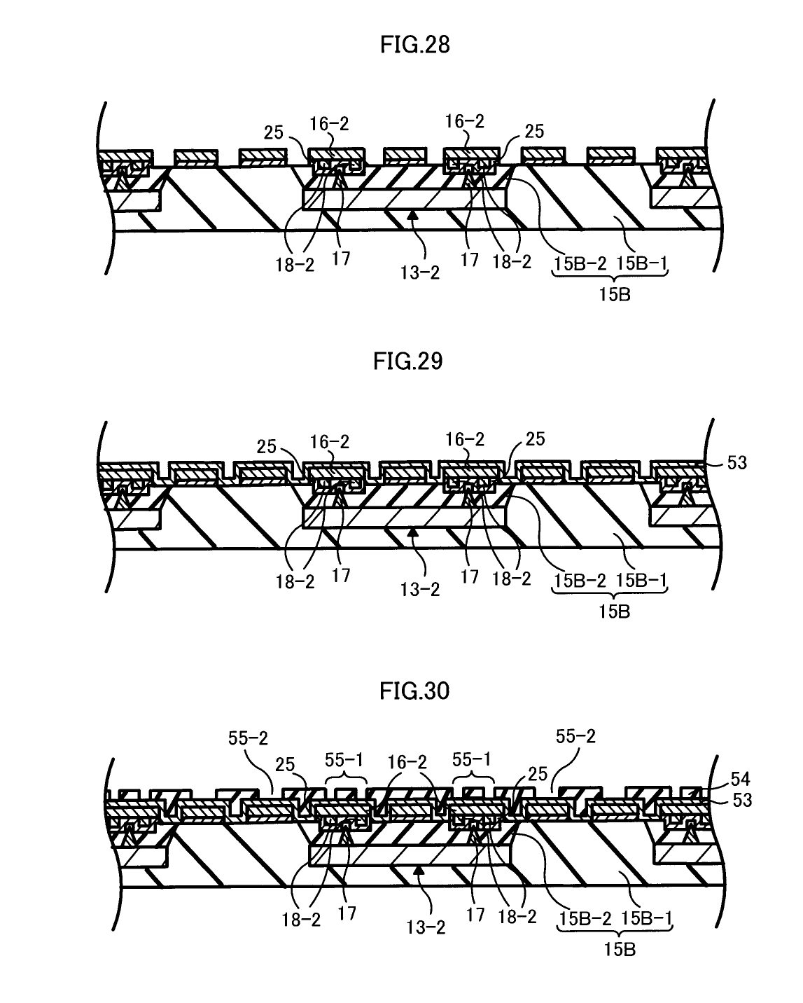

The method for manufacturing the semiconductor device 51 according to the fourth embodiment will be described below. In the method, as illustrated in FIG. 28, after the upper layer of the semiconductor device 51 and the second wiring pattern 16-2 are formed similarly to the first embodiment, the upper layer of the semiconductor device 51 is used as a new support plate, and the lower layer of the semiconductor device 51 is formed on the support plate. The method will be described in detail below with reference to FIGS. 28 to 38. FIGS. 28 to 38 are sectional views taken on the chain line B-B′ of FIG. 5 in order to explain the method for manufacturing the semiconductor device 51 according to the fourth embodiment.

As illustrated in FIG. 28, the constituents to the second wiring pattern 16-2 are formed according to the processes illustrated in FIGS. 5 to 15 in the method for manufacturing the semiconductor device 11 according to the first embodiment. The process, in which an aggregate of the plural second semiconductor chips 13-2 are used as the support plate and the lower layer including the first semiconductor chip 13-1 is formed on the rear surface of the support plate, will be described below.

As illustrated in FIG. 29, for example, a copper metallic film 53 is uniformly formed as a conductive material on the rear surface of the first resin 15B including the second wiring pattern 16-2 by a CVD method. The metallic film 53 constitutes the first connecting plug 18-1 and part of the interlayer connecting post 52 in the subsequent process, and the metallic film 53 is a metallic thin film necessary to form the first connecting plug 18-1 and the interlayer connecting post 52 by the electroplating. Accordingly, the metallic film 53 is not necessarily formed when the first connecting plug 18-1 and the interlayer connecting post 52 can be formed by a method except the metallic plating.

As illustrated in FIG. 30, a photosensitive resist 54 is uniformly formed on the rear surface of the metallic film 53 by using, for example, a spin coater. A cylindrical opening 55-1 and a columnar opening 55-2 are formed in the photosensitive resist 54 by exposing and developing the photosensitive resist 54. The cylindrical opening 55-1 is used to form the first connecting plug 18-1, and the columnar opening 55-2 is used to form the interlayer connecting post 52 later.

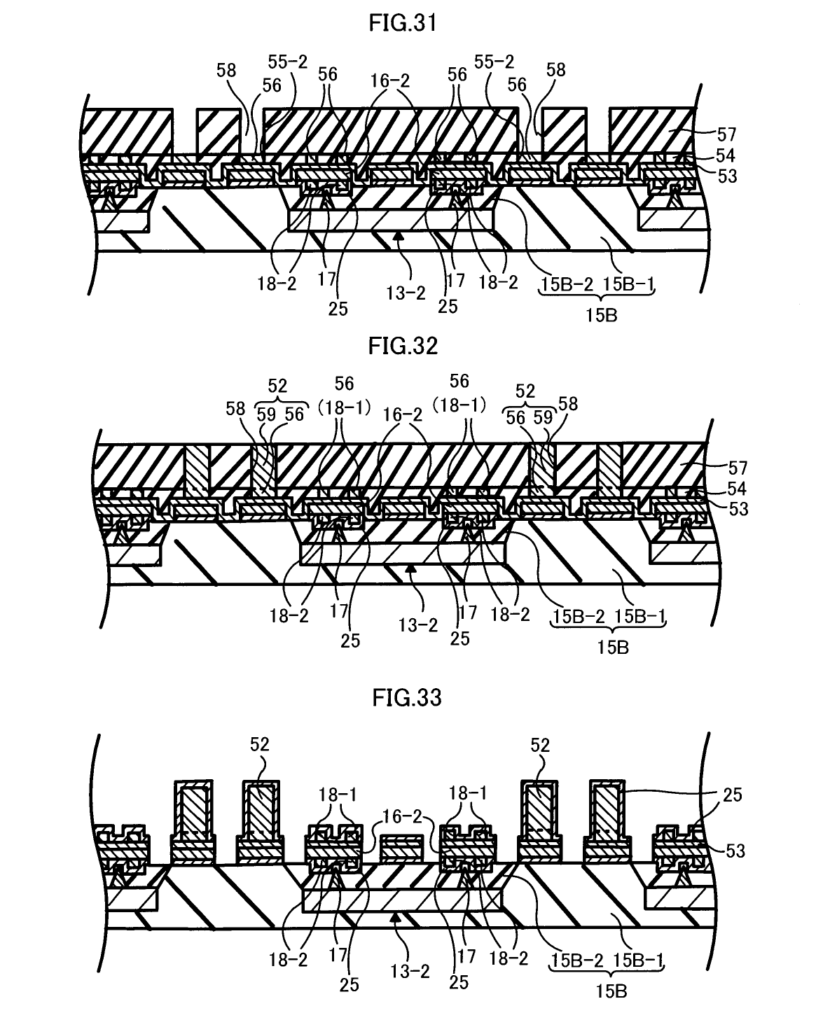

As illustrated in FIG. 31, metals 56 such as copper are formed in the openings 55-1 and 55-2 by, for example, the electroplating. The metal 56 formed in the opening 55-1 constitutes the first connecting plug 18-1. The metal 56 formed in the opening 55-2 partially constitutes the interlayer connecting post 52.

After the first connecting plug 18-1 is formed, a photosensitive resist 57 is uniformly formed on the rear surface of the photosensitive resist 54. A columnar opening 58 is formed in the photosensitive resist 57 by exposing and developing the photosensitive resist 57. The columnar opening 58 is formed on the columnar opening 55-2 so as to have a sectional area equal to a horizontal sectional area of the opening 55-2.

As illustrated in FIG. 32, a metal 59 such as copper is formed in the columnar opening 58 by, for example, the electroplating. The interlayer connecting post 52 is formed by the metal 59 formed through the process of FIG. 32 and the metal 56 formed through the process of FIG. 31.

Then the photosensitive resists 54 and 57 are removed. After the photosensitive resists 54 and 57 are removed, as illustrated in FIG. 33, the surfaces of the second wiring pattern 16-2, first connecting plugs 18-1, and interlayer connecting post 52 are coated with the gold thin film 25 by, for example, the CVD method as necessary in order to prevent the oxidation. Then the metallic film 53 formed below the photosensitive resist 54 and the gold thin film 25 are removed by, for example, the etching. Therefore, the first connecting plug 18-1 and the interlayer connecting post 52 are formed on the rear surface of the second wiring pattern 16-2.

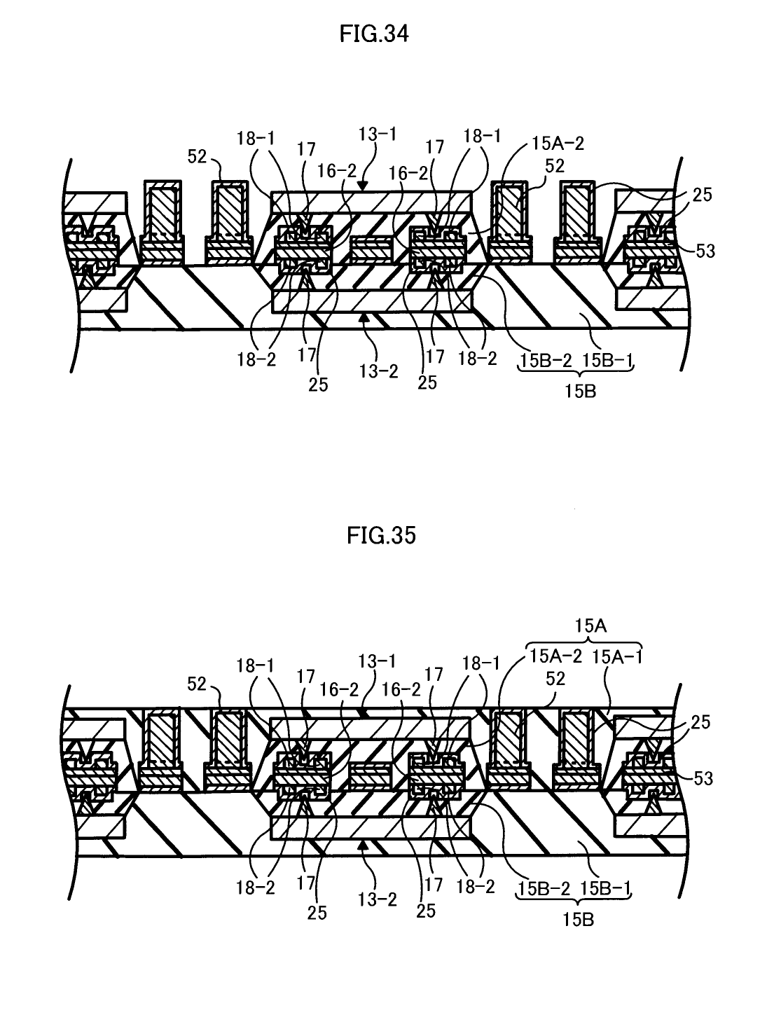

As illustrated in FIG. 34, the plural first semiconductor chips 13-1 are disposed and fixed by the method similar to that illustrated in FIGS. 10 and 11 such that the projected electrode 17 of the first semiconductor chip 13-1 is inserted in and brought into contact with the first connecting plug 18-1. Then the sealing resin 15A-2 is formed between the first semiconductor chip 13-1 and the second wiring pattern 16-2. The plural first semiconductor chips 18-1 are fixed to the rear surface of the second resin layer 15B through the process.

As illustrated in FIG. 35, the resin layer 15A-1 is formed on the rear surface of the second resin layer 15B including the first semiconductor chip 18-1 and the second wiring pattern 16-2 such that the interlayer connecting post 52 is exposed from the rear surface. The first semiconductor chip 13-1 is covered with the first resin layer 15A including the insulating resin 15A-1 and the sealing resin 15A-2 by forming the insulating resin 15A-1.

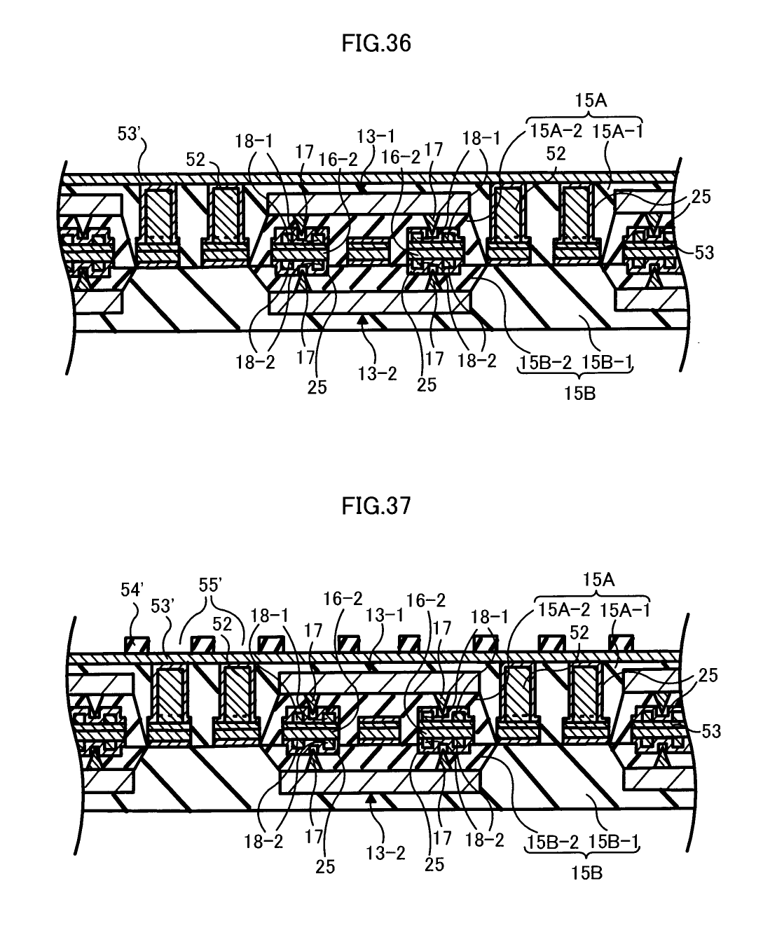

As illustrated in FIG. 36, for example, a copper metallic film 53′ is uniformly formed as a conductive material on the rear surface of the first resin 15A including the interlayer connecting post 52 by the CVD method. The metallic film 53′ constitutes part of the first wiring pattern 16-1 in the subsequent process, and the metallic film 53′ is a metallic thin film necessary to form the first wiring pattern 16-1 by the electroplating. Accordingly, the metallic film 53′ is not necessarily formed when the first wiring pattern 16-1 can be formed by a method except the metallic plating.

As illustrated in FIG. 37, a photosensitive resist 54′ is applied on the rear surface of the metallic film 53′. Then, the photosensitive resist 54′ is exposed and developed using a mask having an opening pattern corresponding to the desired first wiring pattern 16-1, thereby forming an opening pattern 55′ corresponding to the desired first wiring pattern 16-1 in the photosensitive resist 54′.

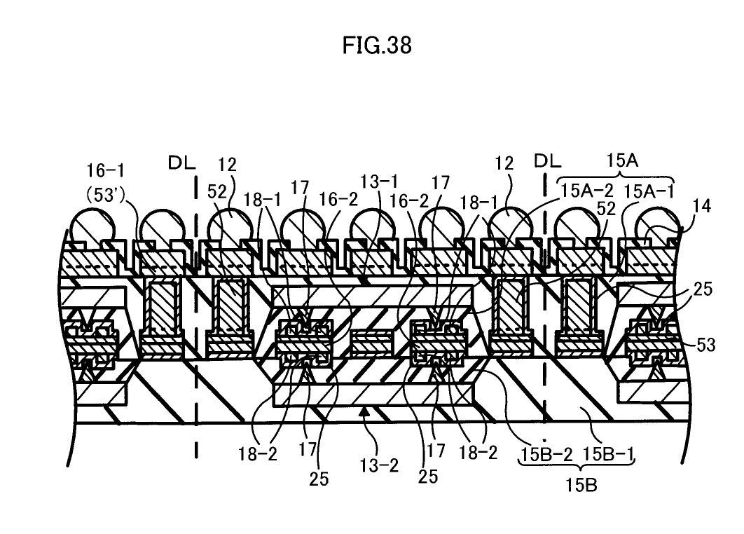

Finally, the metal such as copper is formed in an opening 55′, and the photosensitive resist 54′ is removed. The metallic film 53′ formed below the photosensitive resist 54′ is removed. As illustrated in FIG. 38, the first wiring pattern 16-1 is formed on the rear surface of the first resin layer 15A through the process.

The solder resist film 14 is formed on the whole rear surface of the resin 15A including the wiring pattern 16-1, and the lattice-shaped openings are formed in the solder resist film 14 through the exposure and development processes. Then the solder balls 12 are formed in the openings.

After the solder balls 12 are formed, the solder resist film 14, the insulating resin 15A-1, and the insulating resin 15B-1 are cut along the dicing line DL. The semiconductor device 51 illustrated in FIG. 27 is formed through the cutting process.

The semiconductor device 51 manufactured by the method according to the fourth embodiment has the two-layer structure in which the semiconductor chips 13-1 and 13-2 are stacked. Alternatively, at least three layers of the semiconductor chips 13 may be stacked. In a producing method in such cases, the uppermost layer is formed after the semiconductor device is completed as illustrated in FIG. 28, the processes of FIGS. 29 to 37 are repeated plural times, the lowermost layer is formed after the semiconductor device is completed, and the solder balls and the like are formed according to the process illustrated in FIG. 38.

According to the method for manufacturing the semiconductor device 51 according to the fourth embodiment, the insulating resin 15A-1 is formed such that the first semiconductor chip 13-1 is covered therewith, after the first semiconductor chip 13-1 is disposed and fixed such that the projected electrode 17 of the first semiconductor chip 13-1 is inserted in and brought into contact with the engaging portion of the first connecting plug 18-1. Similarly, the insulating resin 15B-1 is formed such that the second semiconductor chip 13-2 is covered therewith, after the second semiconductor chip 13-2 is disposed and fixed such that the projected electrode 17 of the second semiconductor chip 13-2 is inserted in and brought into contact with the engaging portion of the second connecting plug 18-2. Accordingly, the position deviations of the first and second semiconductor chips 13-1 and 13-2 are suppressed even if the insulating resins 15A-1 and 15B-1 are shrunk during the curing. Accordingly, the failures of the electric connection between the first and second connecting plugs 18-1 and 18-2 and the projected electrode 17 are suppressed, and the plural semiconductor devices 51 can collectively be manufactured without reducing the production yield.

Even in the method for manufacturing the semiconductor device according to the fourth embodiment, the electric conduction between the projected electrode 17 and the first and second connecting plugs 18-1 and 18-2 is established by bringing the projected electrode 17 into contact with the first and second connecting plugs 18-1 and 18-2 while the projected electrode 17 is not melted. Accordingly, the failure of the electric connection associated with the melting of the projected electrode 17 is suppressed.

### Fifth Embodiment

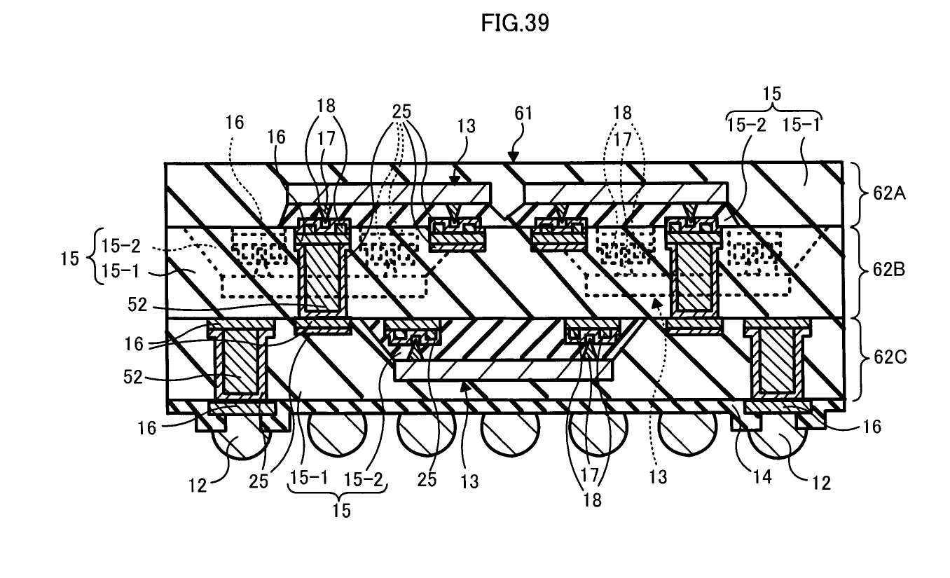

A method for manufacturing a semiconductor device according to a fifth embodiment of the invention will be described below. The rear view of the semiconductor device manufactured by the method according to the fifth embodiment is similar to that illustrated in FIG. 1. Accordingly, the semiconductor device manufactured by the method according to the fifth embodiment will be described with reference to FIG. 39 that is of the sectional view taken on the chain line A-A′ of FIG. 1.

Similarly to the semiconductor device 51 illustrated in FIG. 27, the semiconductor device manufactured by the method for manufacturing the semiconductor device according to the fifth embodiment is a multi-chip module in which the plural semiconductor chips 13 are densely mounted. The semiconductor device produced by the semiconductor device producing method of the fifth embodiment differs from the semiconductor device 51 illustrated in FIG. 27 in the following points.

The semiconductor device manufactured by the method for manufacturing the semiconductor device according to the fifth embodiment has a three-layer structure. The semiconductor chips 13 in the layers are deviated in a direction perpendicular to the paper plane. Other structures of the semiconductor device of the fifth embodiment are identical to those of the semiconductor device 51 illustrated in FIG. 27. Accordingly, the detailed description of the method for manufacturing the semiconductor device according to the fifth embodiment is omitted, and the brief description is made.

As illustrated in FIG. 39, a semiconductor device 61 includes three layers of an uppermost layer 62A, an intermediate layer 62B, and a lowermost layer 62C. In each of the layer 62A to 62C, the semiconductor chip 13 is sealed by the resin 15. The resin 15 includes the sealing resin 15-2 that is of the first resin and the insulating resin 15-1 that is of the second resin. The semiconductor chips 13 constituting the layers 62A to 62C may be identical to or different from one another. Each of the semiconductor chips 13 has the projected electrodes 17 of FIG. 3.

The semiconductor chip 13 is sealed in the intermediate layer 62B by the resin 15 while deviated in the direction perpendicular to the paper plane with respect to the semiconductor chips 13 sealed in the uppermost layer 62A and the lowermost layer 62C.

The wiring patterns 16 are formed at the boundaries between the layers 62A to 62C and in the rear surface of the lowermost layer 62C, respectively. The wiring patterns 16 are electrically connected to one another by the interlayer connecting posts 52 that are provided so as to penetrate the resins 15 of the lowermost layer 62C and intermediate layer 62B.

The plural connecting plugs 18 illustrated in FIG. 4 are formed in the wiring patterns 16 between the layers 62A to 62C. The projected electrodes 17 of the semiconductor chips 13 in the layers of 62A to 62C are inserted in and brought into contact with the connecting plugs 18.

Preferably the gold thin films 25 are formed on the surfaces of the wiring patterns 16 between the layers 62A to 62C, the connecting plugs 18, and the interlayer connecting posts 52 in order to prevent the oxidation of the surfaces.

In a method for manufacturing the semiconductor device 61, the method for manufacturing the semiconductor device 51 illustrated in FIGS. 28 to 37 is repeated to form the three layers of the uppermost layer 62A, the intermediate layer 62B, and the lowermost layer 62C, and then the solder resist film 14 and the solder balls 12 are finally formed as illustrated in FIG. 38.

In the method for manufacturing the semiconductor device 61 according to the fifth embodiment, at least four layers of the plural semiconductor chips 13 may be stacked similarly to the method for manufacturing the semiconductor device 51 according to the fourth embodiment.

According to the method for manufacturing the semiconductor device 61 according to the fifth embodiment, the insulating resin 15-1 is formed such that the semiconductor chip 13 is covered therewith, after the semiconductor chip 13 is disposed and fixed such that the projected electrode 17 of the semiconductor chip 13 is inserted in and brought into contact with the engaging portion of the connecting plug 18. Because the layers 62A to 62C are formed in the above-described way, the position deviations of the semiconductor chips 13 in the layers 62A to 62C are suppressed even if the insulating resins 15-1 constituting the layers 62A to 62C are shrunk during the curing. Accordingly, the failure of the electric connection between the connecting plug 18 and the projected electrode 17 is suppressed, and the plural semiconductor devices 61 can collectively be manufactured without reducing the production yield.

Even in the method for manufacturing the semiconductor device 61 according to the fifth embodiment, the electric conduction can be established between the projected electrode 17 and the connecting plug 18 by bringing the projected electrode 17 into contact with the connecting plug 18 while the projected electrode 17 is not melted. Accordingly, the electric connection failure associated with the melting of the projected electrode 17 is suppressed.

### Sixth Embodiment

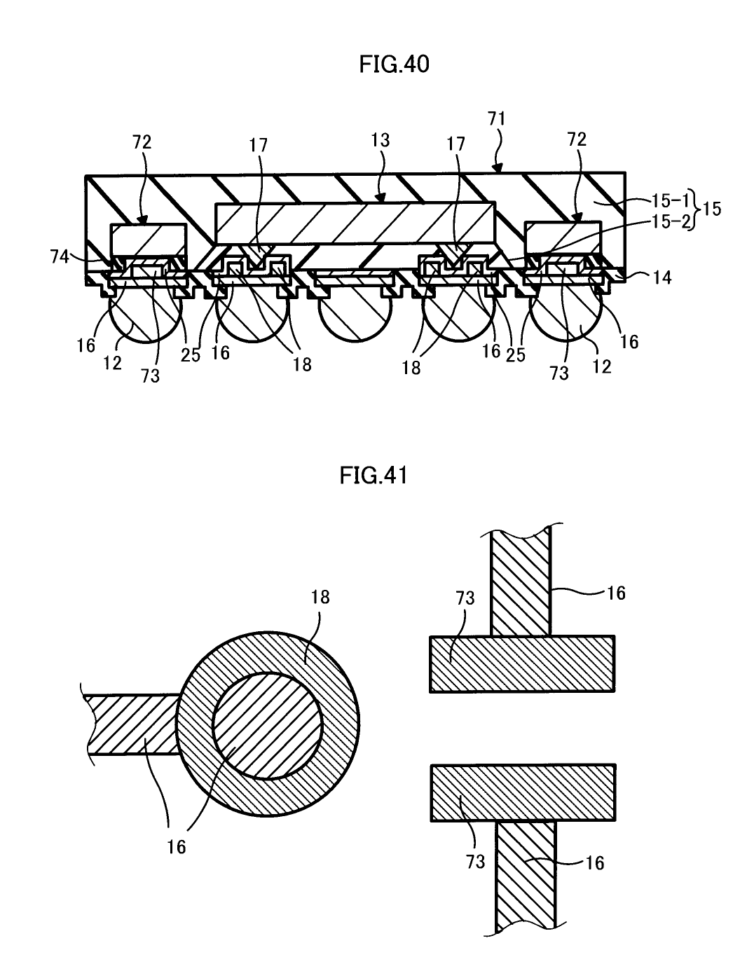

A semiconductor device manufactured by a method for manufacturing the semiconductor device according to a sixth embodiment of the invention will be described below. A rear view of the semiconductor device is similar to that illustrated in FIG. 1. Accordingly, the semiconductor device manufactured by the method according to the sixth embodiment will be described with reference to FIG. 40 that is of the sectional view taken on the chain line A-A′ of FIG. 1. In FIG. 40, the same part as the semiconductor device 11 illustrated in FIG. 2 is designated by the same numeral as the semiconductor device 11 illustrated in FIG. 1, and the description is omitted.

As illustrated in FIG. 40, a semiconductor device 71 differs from the semiconductor device 11 illustrated in FIG. 2 in that chip components 72 are sealed by the resin 15 along with the semiconductor chip 13. The chip component 72 is connected to the wiring pattern 16. The chip component 72 is a passive component such as a resistor and a capacitor.

The connecting plug 18 is formed on the wiring pattern 16 such that the projected electrode 17 of the semiconductor chip 13 is inserted in and brought into contact with the connecting plug 18. The semiconductor chip 13 is connected to the wiring pattern 16 through the connecting plug 18. This point is similar to that of the semiconductor device illustrated in FIG. 2.

A chip component connecting pad 73 is formed on the wiring pattern 16 such that a connection terminal (not illustrated) of the chip component 72 comes into contact therewith. The chip component 72 is connected to the wiring pattern 16 through the chip component connecting pad 73. The connection terminal (not illustrated) of the chip component 72 is an external electrode that is formed so as to be exposed into a rectangular shape from both ends of the lower surface of the chip component 72.

FIG. 41 is an enlarged top view illustrating the connecting plug 18 and the chip component connecting pad 73. As illustrated in FIG. 41, the connecting plug 18 has the cylindrical shape similarly to that of each of the embodiments. On the other hand, the chip component connecting pad 73 has a square pillar shape, and the chip component connecting pad 73 has a rectangular shape in horizontal section. The chip component connecting pads 73 having the square pillar shapes are formed at two points corresponding to the number of connection terminals of the chip component 72. The chip component connecting pads 73 are separated from each other by a distance equal to a distance between the connection terminals of the chip component 72.

Preferably the wiring pattern 16, the connecting plug 18, and the chip component connecting pad 73 are covered with the gold thin film 25 in order to prevent the oxidation of the wiring pattern 16, the connecting plug 18, and the chip component connecting pad 73.

Referring to FIG. 40, a conductive jointing member 74 is provided in the surroundings of the chip component connecting pad 73. The chip component 72 is fixed onto the chip component connecting pad 73 such that the connection terminal of the chip component 72 comes into contact with the chip component connecting pad 73 and such that the lower surface of the chip component 72 comes into contact with the conductive jointing member 74.

The chip component 72 and the semiconductor chip 13 fixed by the sealing resin 15-2 that is of the first resin are covered with the insulating resin 15-1 that is of the second resin.

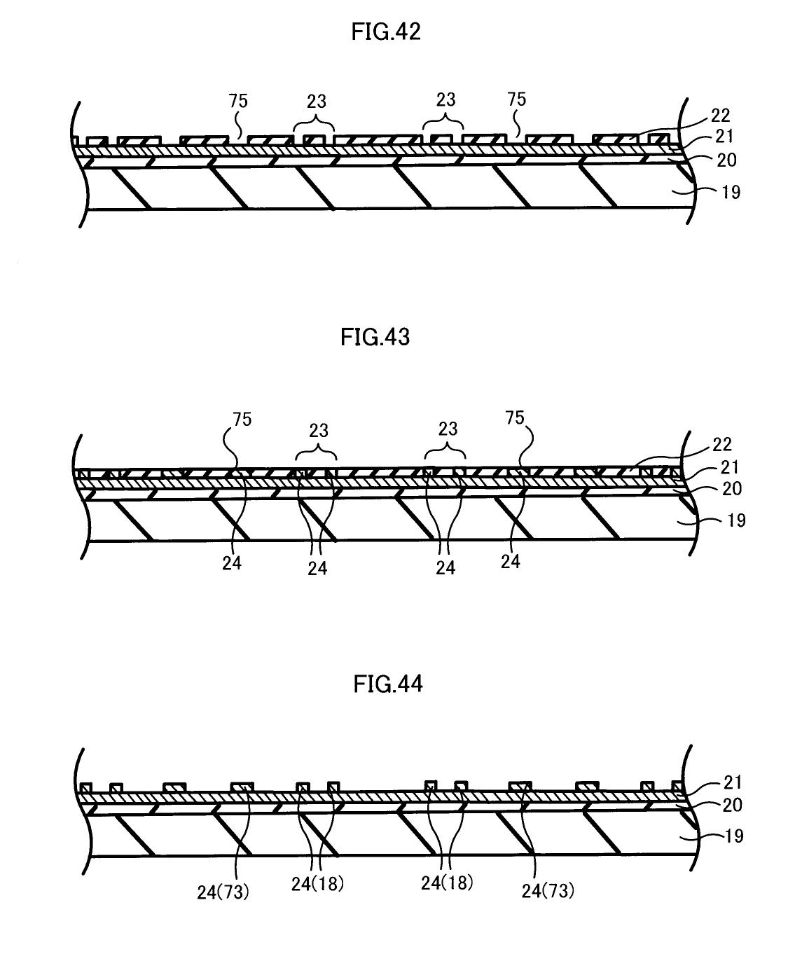

The method for manufacturing the semiconductor device 71 will be described below. The method according to the sixth embodiment is basically similar to the method according to the first embodiment, and the method according to the sixth embodiment differs from the method according to the first embodiment in that the chip component 72 is disposed and fixed along with the semiconductor chip 13. The method according to the sixth embodiment will be described in detail below with reference to FIGS. 42 to 52. FIGS. 42 to 52 are sectional views taken on the chain line B-B′ of FIG. 5 in order to explain the method for manufacturing the semiconductor device 71 according to the sixth embodiment.

For example, the copper metallic film 21 having the thin-plate or foil shape is bonded to the flat support plate 19 made of glass using the heat-resistant bonding agent 20. As illustrated in FIG. 42, the photosensitive resist 22 is uniformly formed on the metallic film 21 by using, for example, the spin coater. Then the cylindrical opening 23 and a square-pillar-shaped opening 75 are formed in the photosensitive resist 22 by exposing and developing the photosensitive resist 22. The cylindrical opening 23 is used to form the first connecting plug 18, and the square-pillar-shaped opening 75 is used to form the chip component connecting pad 73 later.

As illustrated in FIG. 43, the metals 24 such as copper are formed in the cylindrical openings 23 and the square-pillar-shaped opening 75 by, for example, the electroplating.

As illustrated in FIG. 44, the photosensitive resist 22 is removed by, for example, the asking. The cylindrical connecting plug 18 and the square-pillar-shaped chip component connecting pad 73 are formed on the metallic film 21 by removing the photosensitive resist 22.

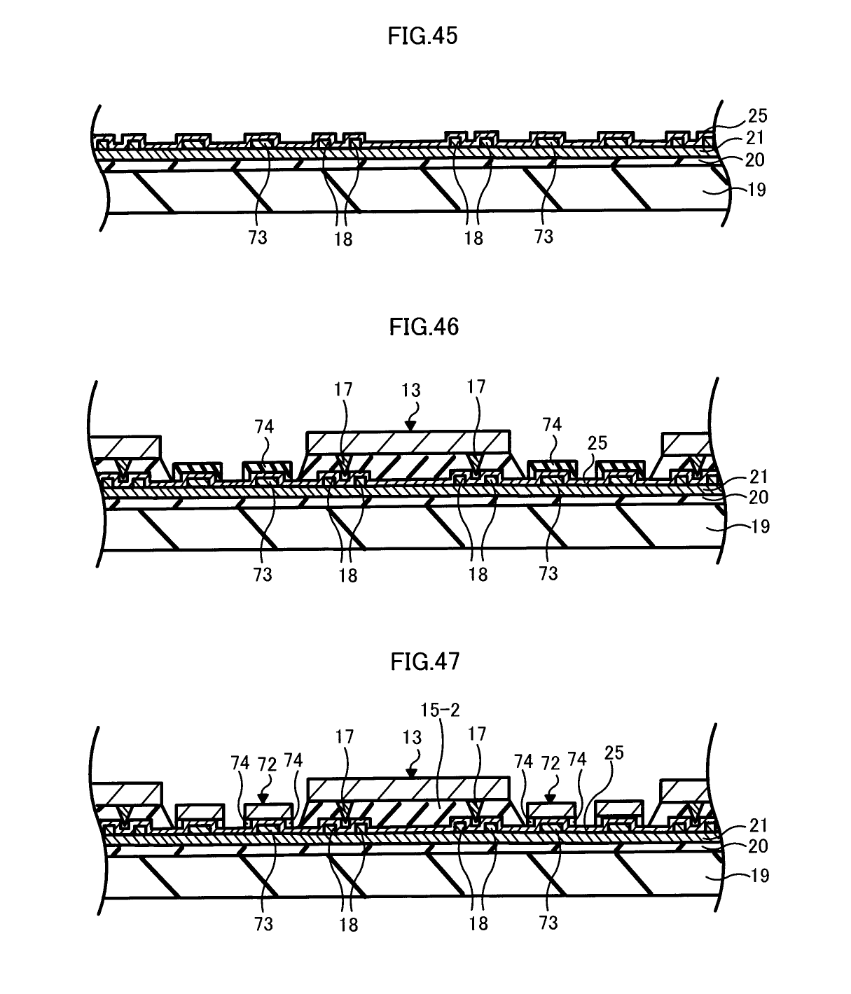

As illustrated in FIG. 45, the gold thin film 25 is formed on the metallic film 21 including the connecting plug 18 and the chip component connecting pad 73 by, for example, the CVD method.

As illustrated in FIG. 46, the semiconductor chip 13 is aligned such that the projected electrode 17 of the semiconductor chip 13 is inserted in and brought into contact with the engaging portion of the connecting plug 18, whereby the semiconductor chip 13 is disposed and fixed onto the metallic film 21. The sealing resin 15-2 is formed between the semiconductor chip 13 and the metallic film 21 including the connecting plug 18. The semiconductor chip 13 is strongly fixed onto the metallic film 21 through the process.

On the other hand, the conductive jointing member 74 is provided in the surroundings of the chip component connecting pad 73. When solder paste is used as the conductive jointing member 74, the conductive jointing member 74 may be provided by a dispensing.

As illustrated in FIG. 47, after the connection terminal (not illustrated) of the chip component 72 and the chip component connecting pad 73 are aligned with each other, the chip component 72 is disposed on the chip component connecting pad 73 and the conductive jointing member 74. Then a suction jig (not illustrated) for the chip component 72 is heated to perform soldering between the connection terminal of the chip component 72 and the chip component connecting pad 73. The chip component 72 is fixed onto the chip component connecting pad 73 by the soldering.

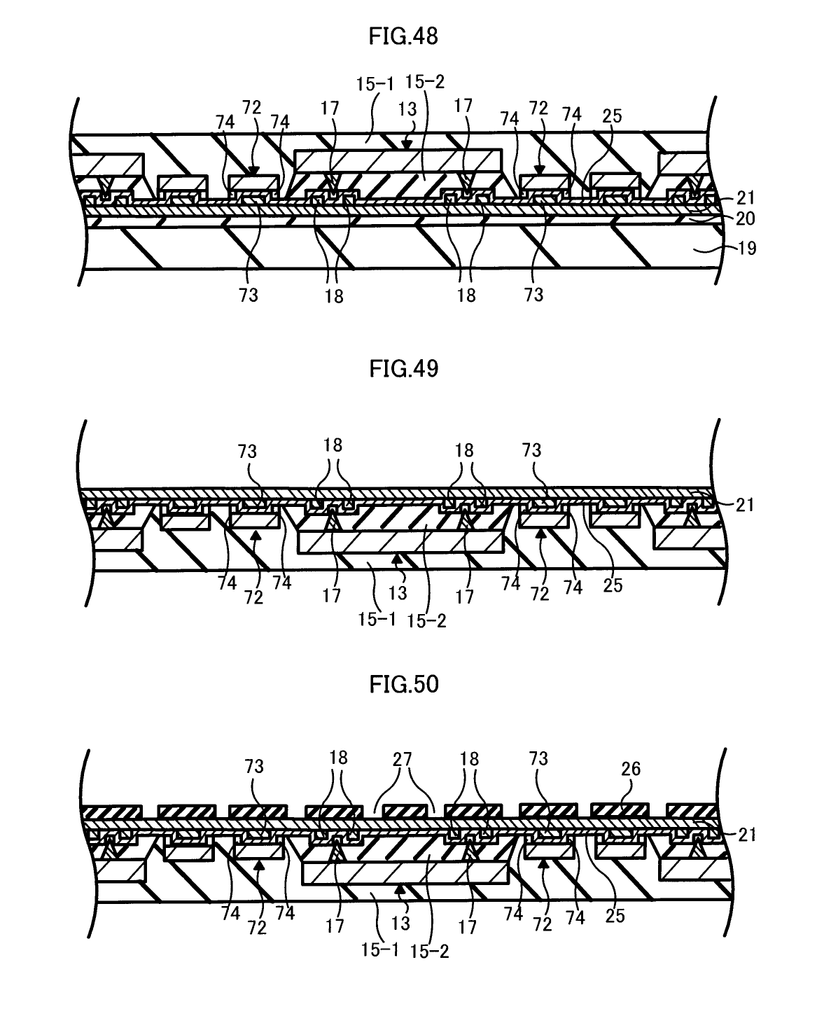

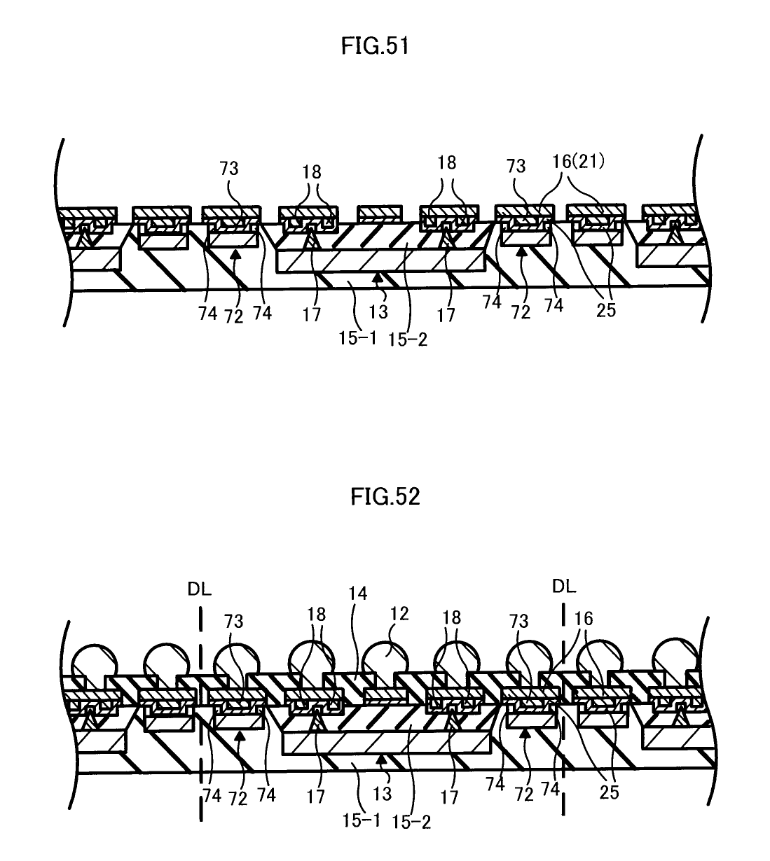

Because the subsequent processes are similar to those illustrated in FIGS. 12 to 16 of the first embodiment, the description is briefly made. As illustrated in FIG. 48, the whole surface of the metallic film 21 including the semiconductor chip 13 and the chip component 72 is covered with the insulating resin 15-1, and the insulating resin 15-1 is cured. As illustrated in FIG. 49, the support plate 19 is peeled off from the metallic film 21, and the whole is inverted. As illustrated in FIG. 50, after the photosensitive resist 26 is applied onto the rear surface of the metallic film 21, the opening 27 corresponding to the desired wiring pattern 16 is formed in the photosensitive resist 26. As illustrated in FIG. 51, the wiring pattern 16 is formed on the rear surface of the resin 15 including the insulating resin 15-1 and the sealing resin 15-2 by etching the metallic film 21 with the photosensitive resist 26 as the resist. Finally, as illustrated in FIG. 52, the solder resist film 14 is formed on the whole surface of the resin 15 including the wiring pattern 16. Then, for example, the lattice-shaped openings are formed in the solder resist film 14 through the exposure and development processes. The solder balls 12 are formed in the openings. Then the solder resist film 14 and the insulating resin 15-1 are cut along the dicing line DL. The semiconductor device 71 of FIG. 40 is manufactured through the cutting process.

According to the method for manufacturing the semiconductor device 71 according to the sixth embodiment, the plural semiconductor chips 13 are disposed and fixed such that the projected electrodes 17 are inserted in and brought into contact with the engaging portions of the connecting plugs 18, and the chip component 72 is bonded to the chip component connecting pad 73 by the soldering. Then the plural semiconductor chips 13 and the plural chip components 72 are sealed by the insulating resin 15-1. Accordingly, the position deviations of the semiconductor chips 13 and chip components 72 are suppressed even if the insulating resin 15-1 is shrunk during the curing. Accordingly, the failure of the electric connection between the connecting plug 18 and the projected electrode 17 is suppressed, and the failure of the electric connection between the chip component connecting pad 73 and the connection terminal of the chip component 72 is also suppressed. Therefore, the plural semiconductor devices 71 can collectively be manufactured without reducing the production yield.

Even in the method for manufacturing the semiconductor device according to the sixth embodiment, the electric conduction can be established between the projected electrode 17 and the connecting plug 18 by bringing the projected electrode 17 into contact with the connecting plug 18 while the projected electrode 17 is not melted. Accordingly, the electric connection failure associated with the melting of the projected electrode 17 is suppressed.

### Seventh Embodiment

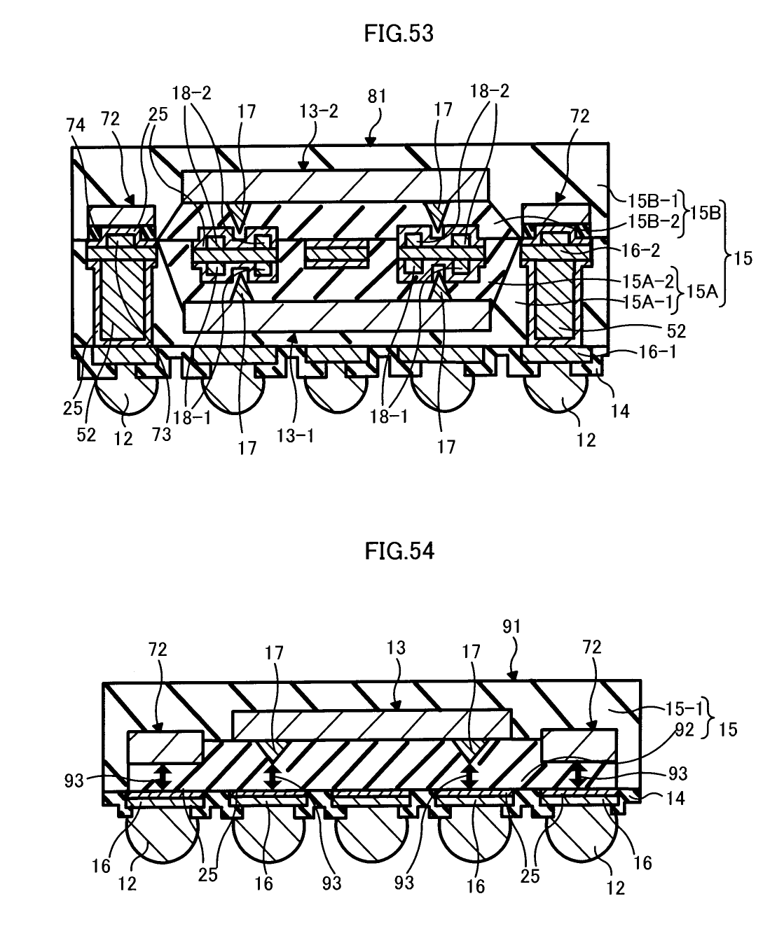

A semiconductor device manufactured by a method for manufacturing the semiconductor device according to a seventh embodiment of the invention will be described below. A rear view of the semiconductor device is similar to that illustrated in FIG. 1. Accordingly, the semiconductor device manufactured by the method according to the seventh embodiment will be described with reference to FIG. 53 that is of the sectional view taken on the chain line A-A′ of FIG. 1. In FIG. 53, the same part as the semiconductor device 51 of FIG. 27 is designated by the same numeral as the semiconductor device 51, and the description is omitted.

As illustrated in FIG. 53, a semiconductor device 81 differs from the semiconductor device 51 manufactured by the method according to the fourth embodiment in that the chip components 72 are formed in the upper layer along with the second semiconductor chip 13-2. The semiconductor device 81 includes two layers of the upper layer and the lower layer, the first semiconductor chip 13-1 is covered with the resin 15 in the lower layer, and the second semiconductor chip 13-2 and the chip component 72 are covered with the resin 15 in the upper layer. That is, the semiconductor device 81 is a multi-chip module on which the first and second semiconductor chips 13-1 and 13-2 and the chip component 72 are densely mounted.

The second connecting plug 18-2 that connects the second semiconductor chip 13-2 and the second wiring pattern 16-2 is formed in a predetermined position on the second wiring pattern 16-2, and the chip component connecting pad 73 that connects the chip component 72 and the second wiring pattern 16-2 is formed in a predetermined position on the second wiring pattern 16-2.

The semiconductor device 81 is manufactured as follows. Similarly to the method for manufacturing the semiconductor device 71 according to the sixth embodiment, the upper layer including the second semiconductor chip 13-2 and the chip component 72 and the second wiring pattern 16-2 are formed according to the method illustrated in FIGS. 42 to 51. After the upper layer is formed, the lower layer including the first semiconductor chip 13-1 is formed on the rear surface of the upper layer including the second wiring pattern 16-2 according to the method illustrated in FIGS. 28 to 38 that is of the method for manufacturing the semiconductor device 51 according to the fourth embodiment. Finally, the first wiring pattern 16-1, the solder resist film 14, and the solder balls 12 are formed on the rear surface of the lower layer. The semiconductor device 81 illustrated in FIG. 53 is manufactured through the processes.

The semiconductor device 81 illustrated in FIG. 53 has the two-layer structure in which the semiconductor chips 13-1 and 13-2 and the chip components 72 are stacked. Alternatively, the plural semiconductor chips 13 and the chip components 72 may be stacked in at least three layers. In the manufacturing method in such cases, as described above in the method for manufacturing the semiconductor device 51 according to the fourth embodiment, after the layer that constitutes the uppermost layer of the semiconductor device is formed, at least one intermediate layer and one lowermost layer are formed on a support substrate while the uppermost layer is used as the support substrate, and the solder balls and the like are finally manufactured.

According to the method for manufacturing the semiconductor device 81 according to the seventh embodiment, the insulating resin 15A-1 is formed such that the first semiconductor chip 13-1 is covered therewith, after the first semiconductor chip 13-1 is disposed and fixed such that the projected electrode 17 of the first semiconductor chip 13-1 is inserted in and brought into contact with the engaging portion of the first connecting plug 18-1. Similarly, the second semiconductor chips 13-2 is disposed and fixed such that the projected electrodes 17 of the second semiconductor chip 13-2 is inserted in and brought into contact with the engaging portion of the second connecting plug 18, and the chip component 72 is bonded to the chip component connecting pad 73 by the soldering. Then the insulating resin 15B-1 is formed such that the plural second semiconductor chips 13-2 and the plural chip components 72 are covered therewith. Accordingly, the position deviations of the first and second semiconductor chips 13-1 and 13-2 and chip components 72 are suppressed even if the insulating resins 15A-1 and 15B-1 are shrunk during the curing. Accordingly, the failure of the electric connection between the connecting plug 18 and the projected electrode 17 is suppressed, and the failure of the electric connection between the chip component connecting pad 73 and the connection terminal of the chip component is also suppressed. Therefore, the plural semiconductor devices 81 can collectively be manufactured without reducing the production yield.

Even in the method for manufacturing the semiconductor device according to the seventh embodiment, the electric conduction can be established between the projected electrode 17 and the connecting plug 18 by bringing the projected electrode 17 into contact with the connecting plug 18 while the projected electrode 17 is not melted. Accordingly, the electric connection failure associated with the melting of the projected electrode 17 is suppressed.

### Eighth Embodiment

A semiconductor device manufactured by a method for the semiconductor device according to an eighth embodiment of the invention will be described below. A plan view illustrating the semiconductor device in viewing the semiconductor device from the rear surface is similar to that illustrated in FIG. 1. Accordingly, the semiconductor device manufactured by the method for the semiconductor device according to the eighth embodiment will be described with reference to FIG. 54 that is of the sectional view taken on the chain line A-A′ of FIG. 1.

As illustrated in FIG. 54, in a semiconductor device 91, the surroundings of the semiconductor chip 13 and chip component 72 are covered with the resin 15.

The wiring pattern 16 is formed in the rear surface of the resin 15. The wiring pattern 16 is covered with the solder resist film 14. In the solder resist film 14, the openings are formed in the regions where the solder balls 12 are formed. The wiring pattern 16 and the solder balls 12 are electrically connected by forming the solder balls 12 in the openings. Although not illustrated, the wiring pattern 16 is partially extended to the outside of the outer peripheral portion of the semiconductor chip 13.

Similarly to the embodiments, the plural projected electrodes 17 are formed in the rear surface of the semiconductor chip 13. As described above in the sixth embodiment, the rectangular connection terminals are exposed from both ends in the rear surface of the chip component 72.

The resin 15 with which the semiconductor chip 91 is covered includes the insulating resin 15-1 such as a mold resin and an anisotropic conductive film 92. The anisotropic conductive film 92 that is of the first resin is formed in a predetermined region on the wiring pattern 16. The semiconductor chip 13 is bonded to the anisotropic conductive film 92 such that the projected electrode 17 of the semiconductor chip 13 is buried in the anisotropic conductive film 92 and such that the rear surface of the semiconductor chip 13 is in contact with the anisotropic conductive film 92. The chip component 72 is bonded to the anisotropic conductive film 92 such that at least the connection terminal of the chip component 72 is in contact with the anisotropic conductive film 92 and such that part of the chip component 72 is buried in the anisotropic conductive film 92. The insulating resin 15-1 that is of the second resin is formed such that the semiconductor chip 13 and chip component 72, which are partially exposed from the anisotropic conductive film 92, are covered therewith.

The anisotropic conductive film 92 is a resin in which the electric conduction is established only in a specific direction while not established in other directions. In the semiconductor device 91, the electric conduction is established only in a perpendicular direction in the anisotropic conductive film 92 as illustrated by arrows 93 in FIG. 54. That is, in the anisotropic conductive film 92, a portion engaged with the projected electrode 17 and a portion between the wiring pattern 16 and the portion engaged with the projected electrode 17 act as the connecting conductor. In the anisotropic conductive film 92, a portion that is in contact with the connection terminal of the chip component 72 and a portion between the wiring pattern 16 and the portion that is in contact with the connection terminal of the chip component 72 act as the chip component connecting pad. The electric conduction is established between the wiring pattern 16 and the projected electrode 17 of the semiconductor chip 13 by the anisotropic conductive film 92, the electric conduction is established between the wiring pattern 16 and the connection terminal (not illustrated) of the chip component 72 by the anisotropic conductive film 92, and the electric conduction is not established between the projected electrode 17 of the semiconductor chip 13 and the connection terminal of the chip component 72.

The semiconductor device 91 is manufactured as follows. The metallic film 21 that constitutes the wiring pattern 16 is bonded onto the support plate 19 by the heat-resistant bonding agent 20. The anisotropic conductive film 92 is bonded in a predetermined position on the metallic film 21. Then the semiconductor chip 13 and the chip component 72 are bonded and fixed onto the anisotropic conductive film 92. The semiconductor chip 13 and the chip component 72 are covered with the insulating resin 15-1, and the support plate 19 is peeled off after the insulating resin 15-1 is cured. Finally, as described above in the embodiments, the wiring pattern 16, the solder resist film 14, and the solder balls 12 are formed in this order, and the dicing is performed to manufacture the semiconductor device 91 illustrated in FIG. 54.

According to the method for manufacturing the semiconductor device 91 according to the eighth embodiment, after the semiconductor chip 13 and the chip component 72 are bonded and fixed to the anisotropic conductive film 92, the whole is sealed by the insulating resin 15-1. Accordingly, the position deviations of the semiconductor chips 13 and chip components 72 are suppressed even if the insulating resin 15-1 is shrunk during the curing. Accordingly, the failure of the electric connection between the semiconductor chip 13, chip component 72 and the wiring pattern 16 is suppressed. Therefore, the plural semiconductor devices 91 can collectively be manufactured without reducing the production yield.

Even in the method for manufacturing the semiconductor device according to the eighth embodiment, the electric conduction can be established between the projected electrode 17 and the wiring pattern 16 by burying the projected electrode 17 in the anisotropic conductive film 92 while the projected electrode 17 is not melted. Accordingly, the electric connection failure associated with the melting of the projected electrode 17 is suppressed.

While certain embodiments have been described, these embodiments have been presented by way of example only, and are not intended to limit the scope of the inventions. Indeed, the novel semiconductor device and the semiconductor device producing method described herein may be embodied in a variety of other forms: furthermore, various omissions, substitutions and changes in the form of semiconductor device and the semiconductor device producing method described herein may be made without departing from the spirit of the inventions. The accompanying claims and their equivalents are intended to cover such forms or modifications as would fall within the scope and spirit of the inventions.

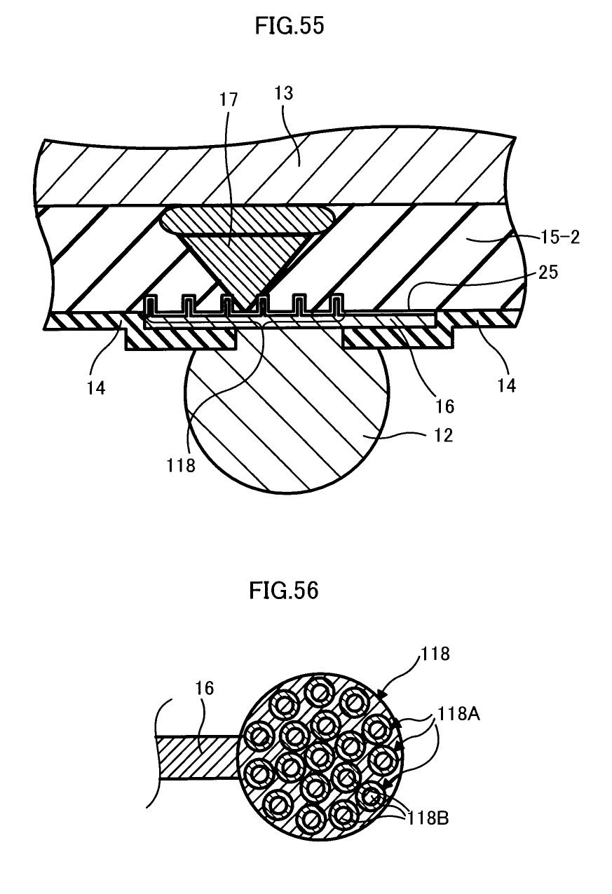

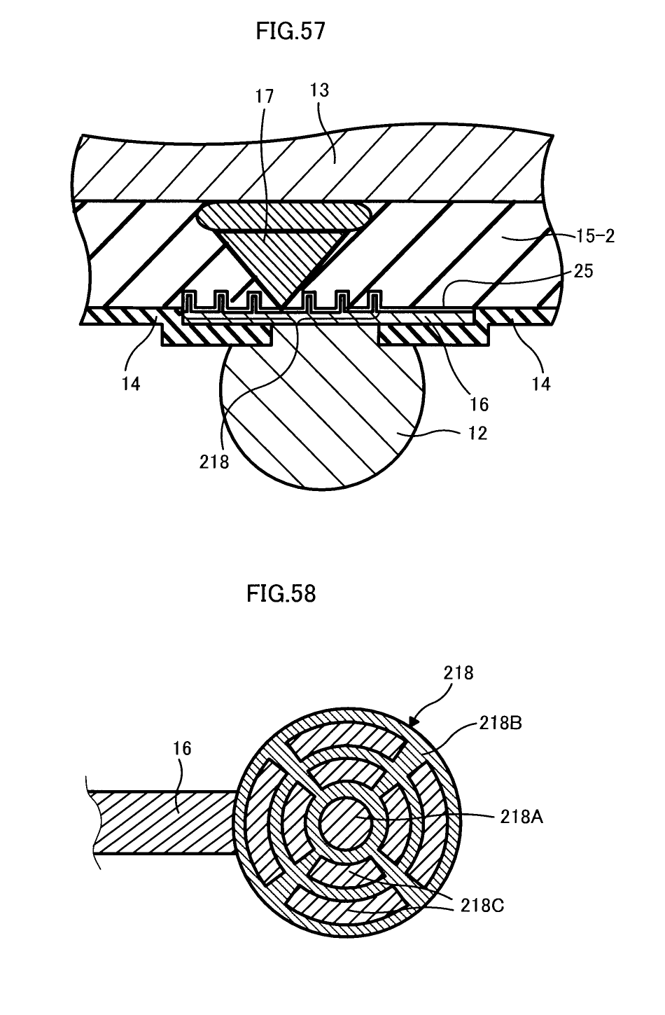

For example, the connecting plug 18 is not limited to the cylindrical shape. FIGS. 55 and 57 are enlarged sectional view taken on the chain line A-A′ of FIG. 1 in order to explain connecting plugs according to modifications. FIG. 56 is a top view of the connecting plug of FIG. 55, and FIG. 58 is a top view of the connecting plug of FIG. 57.

As illustrated in FIGS. 55 and 56, in a connecting plug 118 according to a first modification, plural cylindrical connecting plugs 118A are formed with respect to one projected electrode 17. That is, the connecting plug 118 of the first modification has a structure including plural engaging portions 118B. The plural connecting plugs 118A may regularly be arrayed in a closest packed manner in a region constituting the connecting plug 118, or the plural connecting plugs 118A may randomly be arrayed.

As illustrated in FIGS. 57 and 58, similarly to the connecting plug 18 illustrated in FIG. 4, a connecting plug 218 according to a second modification has a cylindrical shape in which an engaging portion 218A is provided in a central portion, and an engaging portion 218C including plural arc grooves along a circumferential direction is formed in the upper surface of a sidewall portion 218B constituting the cylinder.

For example, when the methods for producing the connecting plugs 118 and 218 are applied to the semiconductor device 11 according to the first embodiment, in the process illustrated in FIG. 6, the openings corresponding to the connecting plugs 118 and 218 are formed in the photosensitive resist 22, and copper is formed in the openings by the electroplating.

When the connecting plugs 118 and 218 according to the first and second modifications, even if the misalignment is generated in some degree in aligning the semiconductor chip 13, the projected electrode 17 is inserted in and brought into contact with any one of the engaging portions 118B, 218A, and 218C provided in the connecting plugs 118 and 218. Accordingly, the accuracy necessary against the misalignment of the semiconductor chip 13 can be lowered to facilitate the production of the semiconductor device.

The embodiments of the invention may appropriately be combined. For example, the method for manufacturing the semiconductor device 31 according to the second embodiment may be applied to the methods for manufacturing the semiconductor devices 51, 61, 71, and 81 according to the fourth to seventh embodiments.

For example, the method for manufacturing of the semiconductor device 41 according to the third embodiment may be applied to the methods for manufacturing the semiconductor devices 51, 61, 71, 81, and 91 according to the fourth to eighth embodiments.

In addition to the embodiments made by the combinations, a metal diffusion preventing treatment may be performed to a region where the wiring pattern 16 (first wiring pattern 16-1) is in contact with the solder ball 12 in the methods for manufacturing the semiconductor devices 11, 31, 41, 51, 61, 71, 81, and 91 according to the embodiments.

What is claimed is:

1. A method for manufacturing a semiconductor device comprising the steps of:
forming a metallic film on a support plate;
forming a plurality of connecting conductors including engaging portions on the metallic film;
inserting and bringing a projected first external electrode provided in each of a plurality of semiconductor chips in and into contact with each of the engaging portions of the plurality of connecting conductors, and forming a first resin between the plurality of semiconductor chips and the metallic film;
covering the plurality of semiconductor chips with a second resin to cure the second resin;
forming a wiring pattern that is electrically connected to the connecting conductor by processing the metallic film;
forming a second external electrode such that the second external electrode is electrically connected to part of the wiring pattern; and
cutting the second resin around and above the plurality of semiconductor chips.

2. The method for manufacturing the semiconductor device according to claim 1, wherein the connecting conductor includes at least one cylindrical metal, and the engaging portion is an inside of the cylindrical metal.

3. The method for manufacturing the semiconductor device according to claim 1, wherein the wiring pattern is partially extended to an outside of an outer peripheral portion of the semiconductor chip.

4. The method for manufacturing the semiconductor device according to claim 1, wherein the connecting conductor includes a cylindrical metal, and the engaging portion includes a plurality of arc grooves that are provided along a circumferential direction in a cylindrical inside and an upper surface of a cylindrical sidewall.

5. The method for manufacturing the semiconductor device according to claim 1, wherein the step of forming the plurality of connecting conductors and the step of forming the first resin are the step of bonding an anisotropic conductive film onto the metallic film.

6. The method for manufacturing the semiconductor device according to claim 1, wherein an aggregate of the plurality of semiconductor chips covered with the second resin is used as a support substrate, and
the semiconductor device producing method further comprises the step of repeating the step of forming a plurality of connecting conductors; the step of forming the first resin; the step of curing the second resin; and the step of forming the wiring pattern in a rear surface of the support substrate including the plurality of semiconductor chips.

7. The method for manufacturing the semiconductor device according to claim 1, wherein
the step of forming the plurality of connecting conductors including the engaging portions further includes the step of forming a plurality of square-pillar-shaped connecting conductor,
the step of forming the first resin includes the step of fixing a plurality of chip components to the plurality of square-pillar-shaped connecting conductors, and
the step of covering the plurality of semiconductor chips with the second resin to cure the second resin is the step of covering the plurality of semiconductor chips and the plurality of chip components with the second resin to cure the second resin.

8. A method for manufacturing a semiconductor device comprising the steps of:
bonding a plurality of semiconductor chips including projected first external electrodes to a surface of a double-side bonding sheet, and bonding a base plate in a position corresponding to each of the plurality of semiconductor chips in a rear surface of the double-side bonding sheet;
covering a plurality of connecting conductors each of which includes at least an engaging portion with a resin;
burying the plurality of semiconductor chips in the resin, and inserting and bringing the first external electrode of each of the plurality of semiconductor chips in and into contact with the engaging portion of the connecting conductor;
curing the resin;
forming a second external electrode such that the second external electrode is electrically connected to a wiring pattern connected to the plurality of connecting conductors; and
cutting the double-side bonding sheet around and above each of the plurality of semiconductor chips and the resin.

9. The method for manufacturing the semiconductor device according to claim 8, wherein the connecting conductor includes at least one cylindrical metal, and the engaging portion is an inside of the cylindrical metal.

10. The method for manufacturing the semiconductor device according to claim 8, wherein the wiring pattern is partially extended to an outside of an outer peripheral portion of the semiconductor chip.

11. The method for manufacturing the semiconductor device according to claim 8, wherein the connecting conductor includes a cylindrical metal, and the engaging portion includes a plurality of arc grooves that are provided along a circumferential direction in a cylindrical inside and an upper surface of a cylindrical sidewall.

12. The method for manufacturing the semiconductor device according to claim 8, wherein the base plate is made of copper, stainless steel, or ceramic.

13. A semiconductor device comprising:
a semiconductor chip in which a projected first external electrode is provided;
a connecting conductor that includes an engaging portion, the first external electrode being inserted in and brought into contact with the engaging portion;
a wiring pattern in which the connecting conductor is formed;
a resin which is formed such that the semiconductor chip and the connecting conductor are covered therewith; and
a second external electrode that is electrically connected to the wiring pattern.

14. The semiconductor device according to claim 13, wherein the connecting conductor includes at least one cylindrical metal, and the engaging portion is an inside of the cylindrical metal.

15. The semiconductor device according to claim 13, wherein the wiring pattern is partially extended to an outside of an outer peripheral portion of the semiconductor chip.

16. The semiconductor device according to claim 13, wherein the connecting conductor includes a cylindrical metal, and the engaging portion includes a plurality of arc grooves that are provided in a cylindrical inside and an upper surface of a cylindrical sidewall.

17. The semiconductor device according to claim 13, wherein the connecting conductor and the resin between the semiconductor chip and the wiring pattern are anisotropic conductive films.

18. The semiconductor device according to claim 13, further comprising a base plate on the semiconductor chip.

19. The semiconductor device according to claim 13, further comprising:
a connecting conductor that includes an engaging portion, the engaging portion being formed in a rear surface of the wiring pattern;
a semiconductor chip in which the first external electrode is inserted in and brought into contact with the engaging portion of the connecting conductor, the engaging portion being formed in the rear surface of the wiring pattern; and
a resin with which the semiconductor chip is covered.

20. The semiconductor device according to claim 13, further comprising:
a square-pillar-shaped connecting conductor that is formed in a surface of the wiring pattern;
a conductive jointing member that is formed around the square-pillar-shaped connecting conductor; and
a chip component that is in contact with the conductive jointing member and the square-pillar-shaped connecting conductor, wherein
the resin is formed such that the semiconductor chip and the chip component are covered therewith.
